(19) United States
(12) Patent Application Publication
(10) Pub. No.: US 2026/0092353 A1
(43) Pub. Date: Apr. 2, 2026

(54) DEPOSITION MASK

(71) Applicant: Samsung Display Co., LTD., Yongin-si (KR)

(72) Inventors: Hyo Yul YOON, Yongin-si (KR); Min Gu KIM, Yongin-si (KR); Kyu Jin CHO, Yongin-si (KR); Kyoung Ah LEE, Yongin-si (KR)

(21) Appl. No.: 19/218,247

(22) Filed: May 24, 2025

(30) Foreign Application Priority Data
Sep. 27, 2024 (KR) 10-2024-0131335

(51) Int. Cl. C23C 14/04; H10K 59/12

(52) U.S. Cl. CPC C23C 14/042; H10K 59/12

(57) ABSTRACT

A deposition mask includes a mask frame in which a cell opening is defined, and a membrane disposed on the mask frame and partitioned into a mask cell area disposed on the cell opening and a grid area disposed on the mask frame not to overlap the cell opening, where a plurality of mask cell areas is defined in the membrane, and the mask cell areas are disposed in a matrix form having a plurality of rows in a first direction and a plurality of columns in a second direction intersecting the first direction.

This application claims priority to Korean Patent Application No. 10-2024-0131335, filed on Sep. 27, 2024, and all the benefits accruing therefrom under 35 U.S.C. § 119, the content of which in its entirety is herein incorporated by reference.

### BACKGROUND

### 1. Field

The present disclosure relates to a deposition mask.

### 2. Description of the Related Art

A head mounted display (HMD) is an image display device that is worn on a user's head in the form of glasses or a helmet and focuses on a distance close to the user's eyes. The head mounted display may realize virtual reality (VR) or augmented reality (AR).

The head mounted display enlarges and displays an image displayed on a small display device using a plurality of lenses. Therefore, a display device applied to the head mounted display may be desired to provide a high-resolution image, for example, an image having a resolution of 3000 pixels per inch (PPI) or higher. To this end, organic light emitting diode on silicon (OLEDoS), which is a high-resolution small-sized organic light emitting display device, may be used as the display device applied to the head mounted display. The OLEDoS is a device that displays an image by disposing an organic light emitting diode (OLED) on a semiconductor wafer substrate including a complementary metal oxide semiconductor (CMOS).

In order to manufacture high-resolution display panels with a resolution of 3000 pixels per inch (PPI) or higher, a high-resolution deposition mask is desired. For example, the deposition mask may be manufactured by forming a membrane having a plurality of pixel openings on a substrate, such as a silicon wafer, and forming cell openings by partially etching the substrate to expose the pixel openings.

The deposition mask may be used in a deposition process for forming organic light emitting layers on a backplane substrate. During the deposition process, the backplane substrate may be disposed on the deposition mask, and a deposition source for providing a vapor deposition material may be disposed on a lower portion of the deposition mask. The vapor deposition material may be deposited on the backplane substrate through the pixel openings of the deposition mask.

### SUMMARY

Embodiments of the present disclosure provide a deposition mask with reduced global warpage.

However, embodiments of the present disclosure are not restricted to those set forth herein. The above and other embodiments of the present disclosure will become more apparent to one of ordinary skill in the art to which the present disclosure pertains by referencing the detailed description of the present disclosure given below.

According to an embodiment of the present disclosure, a deposition mask includes a mask frame in which a cell opening is defined, and a membrane disposed on the mask frame and partitioned into a mask cell area disposed on the cell opening and a grid area disposed on the mask frame not to overlap the cell opening, where a plurality of mask cell areas is defined in the membrane, and the mask cell areas are disposed in a matrix form having a plurality of rows in a first direction and a plurality of columns in a second direction intersecting the first direction.

In an embodiment, a number of the mask cell areas disposed in one of the plurality of rows may be equal to or greater than a number of the mask cell areas disposed in one of the plurality of columns.

In an embodiment, the number of the mask cell areas disposed in one of the plurality of columns may be 70% or greater and 100% or less of the number of the mask cell areas disposed in one of the plurality of rows.

In an embodiment, the number of the mask cell areas disposed in one of the plurality of rows and the number of the mask cell areas disposed in one of the plurality of columns are defined by the following inequality:

$$\vert 1 - \frac{CY}{CX} \vert \leq 0.3 ,$$

where CX denotes the number of the mask cell areas disposed in the one of the plurality of rows, and CY denotes the number of the mask cell areas disposed in the one of the plurality of columns.

In an embodiment, the plurality of mask cell areas may have a same size as each other.

In an embodiment, a length of the mask cell area in the first direction may be equal to or length than a length of the mask cell area in the second direction.

In an embodiment, the length of the mask cell area in the second direction may be 70% or greater and 100% or less of the length of the mask cell area in the first direction.

In an embodiment, the length of the mask cell area in the first direction and the length of the mask cell area in the second direction may satisfy the following inequality:

$$\vert 1 - \frac{CL}{CW} \vert \leq 0.3 ,$$

where CW denotes the length of the mask cell area in the first direction, and CL denotes the length of the mask cell area in the second direction.

In an embodiment, a length of a gap between the mask cell areas in the first direction may be equal to or longer than a length of a gap between the mask cell areas in the second direction.

In an embodiment, the length of a gap between the mask cell areas in the second direction may be 70% or greater and 100% or less of the length of a gap between the mask cell areas in the first direction.

In an embodiment, the length of a gap between the mask cell areas in the first direction and the length of a gap between the mask cell areas in second direction may satisfy the following inequality:

$$\vert 1 - \frac{CIL}{CIW} \vert \leq 0.3 ,$$

where CIW denotes the length of the gap between the mask cell areas in the first direction, and CIL denotes the length of the gap between the mask cell areas in the second direction.

In an embodiment, a number of the mask cell areas disposed in each row may gradually decrease from a row disposed on a center side of the membrane to a row disposed in an outer side of the membrane in the second direction, and a number of the mask cell areas disposed in each column may gradually decrease from a column disposed on a center side of the membrane to a column disposed in an outer side of the membrane in the first direction.

In an embodiment, a total length of the mask cell areas on an imaginary line passing through the center side of the membrane and extending in the first direction may satisfy equal to or longer than a total length of the mask cell areas on an imaginary line passing through the center side of the membrane and extending in a fourth direction intersecting the first direction and the second direction.

In an embodiment, the first direction and the second direction may satisfy orthogonal to each other, and the fourth direction may intersect the first direction or the second direction at an angle of about 45°.

In an embodiment, the total length of the mask cell areas on an imaginary line passing through the center side of the membrane and extending in a fourth direction intersecting the first direction and the second direction may satisfy 70% or greater and 100% or less of the total length of the mask cell areas on an imaginary line passing through the center side of the membrane and extending in the first direction.

In an embodiment, the total length of the mask cell areas on an imaginary line passing through the center side of the membrane and extending in the first direction and the total length of the mask cell areas on an imaginary line passing through the center side of the membrane and extending in a fourth direction intersecting the first direction and the second direction may satisfy the following inequality:

$$\vert 1 - \frac{CTDL}{CTWL} \vert \leq 0.3 ,$$

where CTWL denotes the total length of the mask cell areas on the imaginary line extending in the first direction, and CTDL denotes the total length of the mask cell areas on the imaginary line extending in the fourth direction.

In an embodiment, a plurality of pixel openings may be defined through the membrane in the mask cell area.

In an embodiment, the membrane may include an inorganic film layer disposed on the mask frame, and a nitride layer disposed on the inorganic film layer.

In an embodiment, the deposition mask may further include a first rear inorganic film layer disposed below the mask frame with a first rear opening defined therein, a second rear inorganic film layer disposed below the first rear inorganic film layer with a second rear opening defined therein.

In an embodiment, the first rear inorganic film layer may include a same material as the inorganic film layer, and the second rear inorganic film layer may include a same material as the nitride layer.

According to an embodiment of the present disclosure, an electronic device includes a display device manufactured by a deposition mask, where the deposition mask includes a mask frame in which a cell opening is defined, and a membrane disposed on the mask frame and partitioned into a mask cell area disposed on the cell opening and a grid area disposed on the mask frame not to overlap the cell opening, where a plurality of mask cell areas is provided in the membrane, and the mask cell areas are disposed in a matrix form having a plurality of rows in a first direction and a plurality of columns in a second direction intersecting the first direction.

In embodiments of the deposition mask according to the present disclosure, deposition defects are effectively prevented by reducing global warpage by adjusting the size or arrangement shape of a plurality of mask cell areas.

The effects according to the embodiments of the present disclosure are not limited to those mentioned above and more various effects are included in the following description of the present disclosure.

### BRIEF DESCRIPTION OF THE DRAWINGS

The above and other features of embodiments of the present disclosure will become more apparent by describing in detail embodiments thereof with reference to the attached drawings, in which:

FIG. 1 is a schematic exploded perspective view illustrating a display device according to an embodiment;

FIG. 2 is a schematic plan view for describing the display device illustrated in FIG. 1;

FIG. 3 is an equivalent circuit diagram illustrating an example of a first sub-pixel illustrated in FIG. 2;

FIG. 4 is a schematic plan view illustrating an example of a display panel illustrated in FIG. 1;

FIG. 5 is a schematic enlarged plan view illustrating an example of a display area of FIG. 4;

FIG. 6 is a schematic enlarged plan view illustrating another example of the display area of FIG. 4;

FIG. 7 is a schematic cross-sectional view illustrating an example of the display panel taken along line I1-I1′ of FIG. 5;

FIG. 8 is a schematic cross-sectional view illustrating another example of the display panel taken along line I1-I1′ of FIG. 5;

FIG. 9 is a perspective view illustrating an example of a head mounted display device;

FIG. 10 is an exploded perspective view for describing the head mounted display device of FIG. 9;

FIG. 11 is a perspective view illustrating another example of a head mounted display device;

FIG. 12 is a schematic view illustrating a deposition device according to an embodiment;

FIG. 13 is a schematic bottom view illustrating a backplane substrate illustrated in FIG. 12;

FIG. 14 is a schematic plan view illustrating a deposition mask according to an embodiment of the present disclosure;

FIG. 15 is a schematic enlarged plan view illustrating mask cell areas illustrated in FIG. 14;

FIG. 16 is a cross-sectional view taken along line I2-I2′ of FIG. 15;

FIG. 17 is a plan view illustrating a state in which the number of mask cell areas in FIG. 14 is changed;

FIGS. 18 and 19 are enlarged views of part A of FIG. 14; and

FIG. 20 is a plan view illustrating a state in which an arrangement shape of the mask cell areas in FIG. 14 is changed.

FIG. 21 is a block diagram of an electronic device according to an embodiment of the present disclosure.

FIG. 22 is a schematic diagram of an electronic device according to various embodiments of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Features of various embodiments of the present disclosure may be combined partially or totally. As will be clearly appreciated by those skilled in the art, technically various interactions and operations are possible. Various embodiments can be practiced individually or in combination.

Hereinafter, embodiments of the present disclosure will be described in detail with reference to the accompanying drawings.

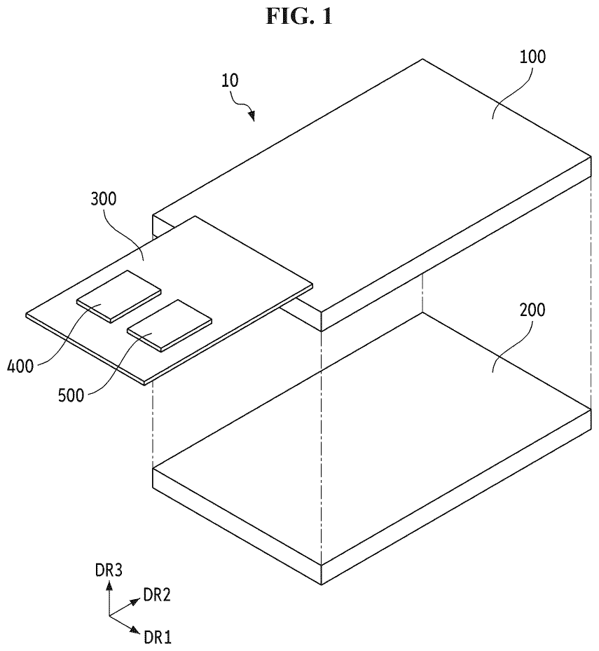

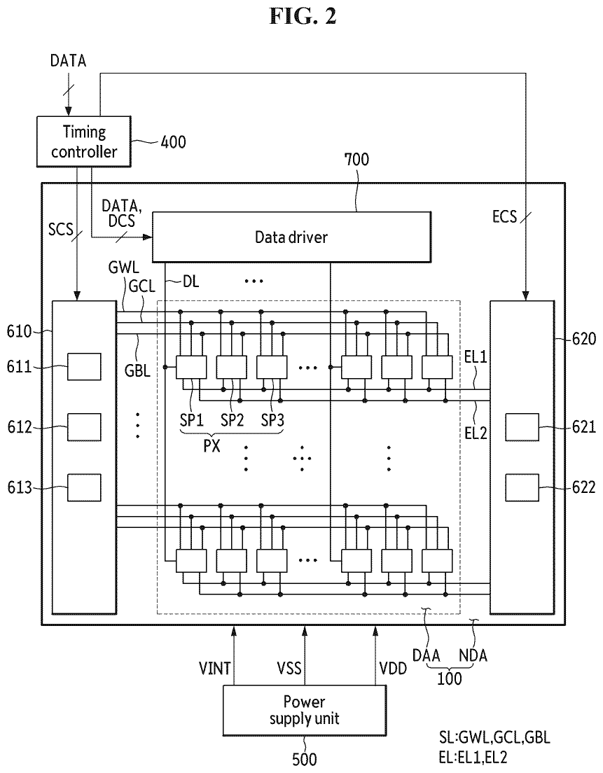

FIG. 1 is a schematic exploded perspective view illustrating a display device according to an embodiment. FIG. 2 is a schematic plan view for describing the display device illustrated in FIG. 1.

Referring to FIGS. 1 and 2, a display device 10 according to an embodiment is a device that displays a moving image or a still image. The display device 10 according to an embodiment may be applied to portable electronic devices such as a mobile phone, a smart phone, a tablet personal computer (PC), a mobile communication terminal, an electronic notebook, an electronic book, a portable multimedia player (PMP), navigation, and an ultra mobile PC (UMPC). For example, the display device 10 according to an embodiment may be applied to a display unit of a television (TV), a laptop computer, a monitor, a billboard, or the Internet of Things (IoT). Alternatively, the display device 10 according to an embodiment may be applied to a smart watch, a watch phone, and a head mounted display (HMD) for implementing virtual reality and augmented reality.

The display device 10 according to an embodiment includes a display panel 100, a heat dissipation layer 200, a circuit board 300, a timing control circuit 400, and a power supply circuit 500.

The display panel 100 may be formed in a planar shape similar to a quadrangle when viewed in a plan view. In an embodiment, for example, the display panel 100 may have a planar shape similar to a quadrangle having short sides in a first direction DR1 and long sides in a second direction DR2 intersecting the first direction DR1 when viewed in a third direction DR3, which is a thickness direction of the display panel 100. In the display panel 100, a corner where the short side in the first direction DR1 and the long side in the second direction DR2 meet may be rounded to have a predetermined curvature or may be formed at a right angle. The planar shape of the display panel 100 is not limited to the quadrangle, and may be formed similarly to other polygons, circles, or ovals. A planar shape of the display device 10 may follow the planar shape of the display panel 100, but the embodiment of the present specification is not limited thereto.

In an embodiment, as shown in FIG. 2, the display panel 100 includes a plurality of pixels PX, a plurality of scan lines SL, a plurality of emission control lines EL, a plurality of data lines DL, a scan driver 610, a light emitting driver 620, and a data driver 700. The display panel 100 may be divided into a display area DAA for displaying an image and a non-display area NDA that does not display an image, as illustrated in FIG. 2.

The plurality of pixels PX may be disposed in the display area DAA. The plurality of pixels PX may be arranged in a matrix form in the first direction DR1 and the second direction DR2. The plurality of scan lines SL and the plurality of emission control lines EL may extend in the first direction DR1 and may be disposed (or arranged) in the second direction DR2. The plurality of data lines DL may extend in the second direction DR2 and may be disposed (or arranged) in the first direction DR1.

The plurality of scan lines SL includes a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

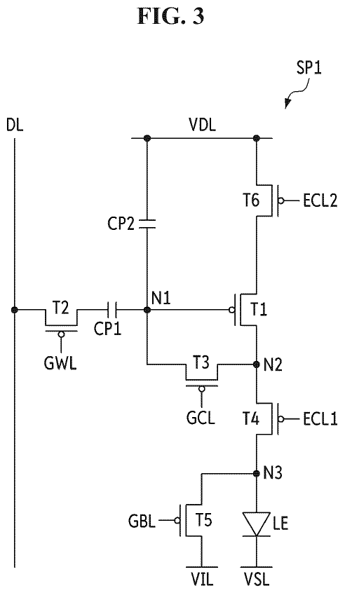

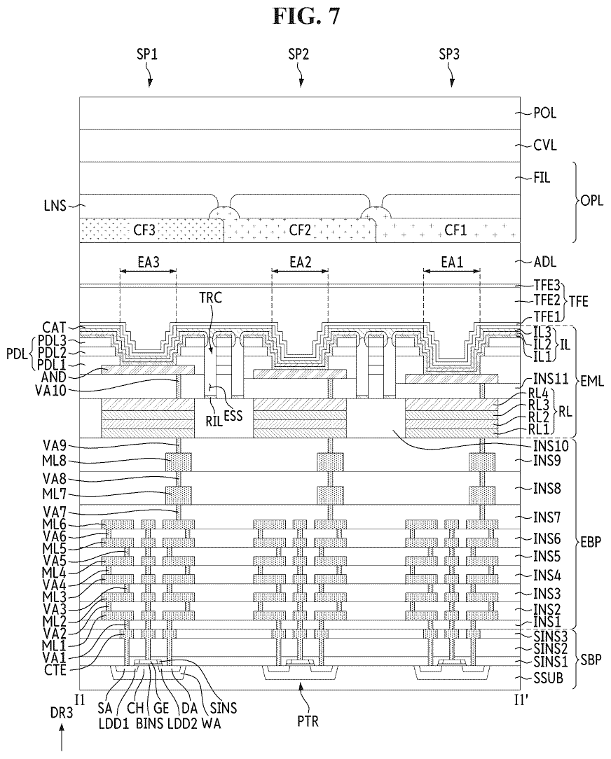

The plurality of pixels PX include a plurality of sub-pixels SP1, SP2, and SP3. The plurality of sub-pixels SP1, SP2, and SP3 may include a plurality of pixel transistors as illustrated in FIG. 3, and the plurality of pixel transistors may be formed through a semiconductor process and may be disposed on a semiconductor substrate (SSUB in FIG. 7). In an embodiment, for example, the plurality of pixel transistors of the data driver 700 may include or be formed of a complementary metal oxide semiconductor (CMOS), but the embodiment of the present specification is not limited thereto.

Each of the plurality of sub-pixels SP1, SP2, and SP3 may be connected to a corresponding write scan line GWL, a corresponding control scan line GCL, a corresponding bias scan line GBL, a corresponding first emission control line ECL1, a corresponding second emission control line ECL2, and a corresponding data line DL. Each of the plurality of sub-pixels SP1, SP2, and SP3 may receive a data voltage of the data line DL based on a write scan signal of the write scan line GWL, and may emit light from a light emitting element based on the data voltage.

The scan driver 610, the light emitting driver 620, and the data driver 700 may be disposed in the non-display area NDA.

The scan driver 610 includes a plurality of scan transistors, and the light emitting driver 620 includes a plurality of light emitting transistors. The plurality of scan transistors and the plurality of light emitting transistors may be formed through a semiconductor process and may be formed on a semiconductor substrate (SSUB in FIG. 7). In an embodiment, for example, the plurality of scan transistors and the plurality of light emitting transistors may include or be formed of CMOS, but the embodiment of the present specification is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals based on the scan timing control signal SCS of the timing control circuit 400 and sequentially output the write scan signals to the write scan lines GWL. The control scan signal output unit 612 may generate control scan signals based on the scan timing control signal SCS and sequentially output the control scan signals to the control scan lines GCL. The bias scan signal output unit 613 may generate bias scan signals based on the scan timing control signal SCS and sequentially output the bias scan signals to the bias scan lines GBL.

The light emitting driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals based on the emission timing control signal ECS and sequentially output the first emission control signals to the first emission control lines ECL1. The second emission control driver 622 may generate second emission control signals based on the emission timing control signal ECS and sequentially output the second emission control signals to the second emission control lines ECL2.

The data driver 700 may include a plurality of data transistors, and the plurality of data transistors may be formed through a semiconductor process and may be formed on a semiconductor substrate (SSUB in FIG. 7). In an embodiment, for example, the plurality of data transistors may be formed of CMOS, but the embodiment of the present specification is not limited thereto.

The data driver 700 may receive digital video data DATA and a data timing control signal DCS from the timing control circuit 400. The data driver 700 converts the digital video data DATA into analog data voltages based on the data timing control signal DCS and outputs the converted analog data voltages to the data lines DL. In this case, the sub-pixels SP1, SP2, and SP3 may be selected by the write scan signals of the scan driver 610, and the data voltages may be supplied to the selected sub-pixels SP1, SP2, and SP3.

The heat dissipation layer 200 may overlap the display panel 100 in the third direction DR3, which is a thickness direction of the display panel 100. The heat dissipation layer 200 may be disposed on one surface of the display panel 100, for example, a rear surface thereof. The heat dissipation layer 200 serves to dissipate heat generated from the display panel 100. The heat dissipation layer 200 may include a metal layer such as graphite, silver (Ag), copper (Cu), or aluminum (Al) having high thermal conductivity.

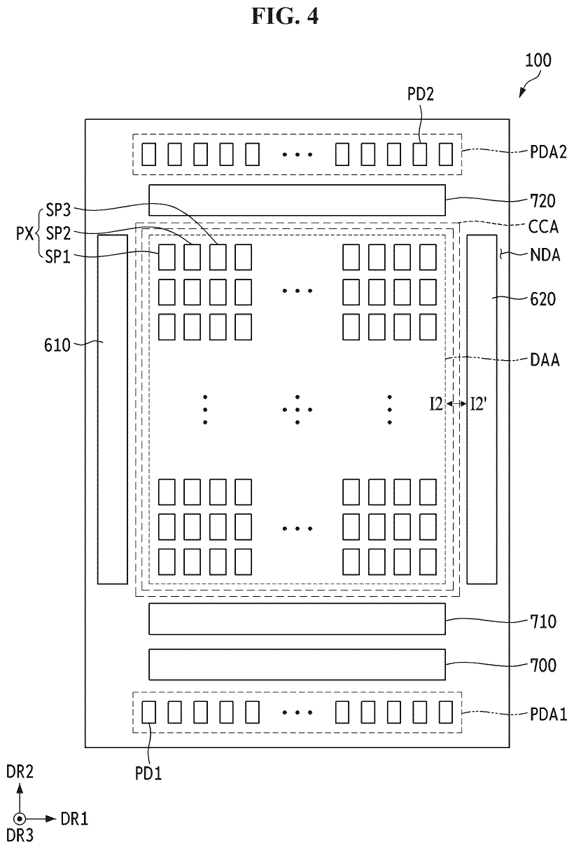

The circuit board 300 may be electrically connected to a plurality of first pads (PD1 in FIG. 4) of a first pad portion (PDA1 in FIG. 4) of the display panel 100 by using a conductive adhesive member such as an anisotropic conductive film. The circuit board 300 may be a flexible printed circuit board or flexible film including or made of a flexible material. FIG. 1 illustrates an embodiment where the circuit board 300 is in an unfolded state, but the circuit board 300 may be bent. In a state where the circuit board 300 is bent, one end of the circuit board 300 may be disposed on the rear surface of the display panel 100 and/or a rear surface of the heat dissipation layer 200. The other end of the circuit board 300 may be connected to a plurality of first pads (PD1 in FIG. 4) of a first pad portion (PDA1 in FIG. 4) of the display panel 100 by using a conductive adhesive material. One end of the circuit board 300 may be an end opposite to the other end of the circuit board 300.

The timing control circuit 400 may receive digital video data and timing signals from the outside (or an external device or circuit). The timing control circuit 400 may generate a scan timing control signal SCS, an emission timing control signal ECS, and a data timing control signal DCS for controlling the display panel 100 based on the timing signals. The timing control circuit 400 may output the scan timing control signal SCS to the scan driver 610 and output the emission timing control signal ECS to the light emitting driver 620. The timing control circuit 400 may output the digital video data and the data timing control signal DCS to the data driver 700.

The power supply circuit 500 may generate a plurality of panel driving voltages based on a power voltage from the outside. In an embodiment, for example, the power supply circuit 500 may generate a first driving voltage VSS, a second driving voltage VDD, and a third driving voltage VINT and supply the generated driving voltages to the display panel 100. The first driving voltage VSS, the second driving voltage VDD, and the third driving voltage VINT will be described later in greater detail with reference to FIG. 3.

In an embodiment, each of the timing control circuit 400 and the power supply circuit 500 may be formed as an integrated circuit (IC) and attached to one surface of the circuit board 300. In such an embodiment, the scan timing control signal SCS, the emission timing control signal ECS, the digital video data DATA, and the data timing control signal DCS of the timing control circuit 400 may be supplied to the display panel 100 through the circuit board 300. In an embodiment, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the light emitting driver 620, and the data driver 700. In such an embodiment, the timing control circuit 400 may include a plurality of timing transistors, and each of the power supply circuits 500 may include a plurality of power transistors. The plurality of timing transistors and the plurality of power transistors may be formed through a semiconductor process and may be formed on a semiconductor substrate (SSUB in FIG. 7). In an embodiment, for example, the plurality of timing transistors and the plurality of power transistors may include or be formed of CMOS, but the embodiment of the present specification is not limited thereto. Each of the timing control circuit 400 and the power supply circuit 500 may be disposed between the data driver 700 and the first pad portion (PDA1 in FIG. 4).

FIG. 3 is an equivalent circuit diagram illustrating an example of a first sub-pixel illustrated in FIG. 2.

Referring to FIG. 3, in an embodiment, the first sub-pixel SP1 may be connected to the write scan line GWL, the control scan line GCL, the bias scan line GBL, the first emission control line ECL1, the second emission control line ECL2, and the data line DL. In addition, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 includes a plurality of transistors T1 to T6, a light emitting element LE, a first capacitor CP1, and a second capacitor CP2.

The light emitting element LE emits light corresponding to a driving current (Ids) flowing through a channel of a first transistor T1. An amount of light emitted from the light emitting element LE may be proportional to the driving current (Ids). A first electrode of the light emitting element LE may be an anode electrode, and a second electrode of the light emitting element LE may be a cathode electrode. In an embodiment, the light emitting element LE may be an organic light emitting diode including a first electrode, a second electrode, and an organic light emitting layer disposed between the first electrode and the second electrode, but the embodiment of the present specification is not limited thereto. In another embodiment, for example, the light emitting element LE may be an inorganic light emitting element including a first electrode, a second electrode, and an inorganic semiconductor disposed between the first electrode and the second electrode. In such an embodiment, the light emitting element LE may be a micro light emitting diode.

The first transistor T1 may be a driving transistor that controls a source-drain current (Ids, hereinafter, referred to as “driving current”) flowing between a source electrode and a drain electrode based on a voltage applied to a gate electrode.

A second transistor T2 may be connected between one electrode of the first capacitor CP1 and the data line DL. The second transistor T2 is turned on by the write scan signal of the write scan line GWL and connects one electrode of the first capacitor CP1 to the data line DL. Accordingly, the data voltage of the data line DL may be applied to one electrode of the first capacitor CP1.

A third transistor T3 may be connected between a first node N1 and a second node N2. The third transistor T3 is turned on by the write control signal of the write control line GCL and connects the first node N1 to the second node N2. Accordingly, when the gate electrode and the source electrode of the first transistor T1 are connected, the first transistor T1 may operate like a diode.

A fourth transistor T4 may be connected between the second node N2 and a third node N3. The fourth transistor T4 is turned on by the first emission control signal of the first emission control line ECL1 and connects the second node N2 to the third node N3. Accordingly, the driving current of the first transistor T1 may be supplied to the light emitting element LE. A fifth transistor T5 may be connected between the third node N3 and the third driving voltage line VIL. The fifth transistor T5 is turned on by the bias scan signal of the bias scan line GBL and connects the third node N3 to the third driving voltage line VIL. Accordingly, the third driving voltage VINT of the third driving voltage line VIL may be applied to the first electrode of the light emitting element LE.

A sixth transistor T6 may be connected between the source electrode of the first transistor T1 and the second driving voltage line VDL. The sixth transistor T6 is turned on by the second emission control signal of the second emission control line ECL2 and connects the source electrode of the first transistor T1 to the second driving voltage line VDL. Accordingly, the second driving voltage VDD of the second driving voltage line VDL may be applied to the source electrode of the first transistor T1.

The first capacitor CP1 is defined or formed between the first node N1 and the drain electrode of the second transistor T2. The second capacitor CP2 is defined or formed between the gate electrode of the first transistor T1 and the second driving voltage line VDL.

Each of the first to sixth transistors T1 to T6 may be a metal-oxide-semiconductor field effect transistor (MOSFET). In an embodiment, for example, each of the first to sixth transistors T1 to T6 may be a p-type MOSFET, but the embodiment of the present specification is not limited thereto. Each of the first to sixth transistors T1 to T6 may be an n-type MOSFET. Alternatively, each of some of the first to sixth transistors T1 to T6 may be a p-type MOSFET, and each of the remaining transistors may be an n-type MOSFET.

FIG. 3 illustrates an embodiment where the first sub-pixel SP1 includes six transistors T1 to T6 and two capacitors CP1 and CP2, but it should be noted that the equivalent circuit diagram of the first sub-pixel SP1 is not limited to that illustrated in FIG. 3. In an embodiment, for example, the number of transistors and capacitors of the first sub-pixel SP1 is not limited to that illustrated in FIG. 3.

In addition, an equivalent circuit diagram of a second sub-pixel SP2 and an equivalent circuit diagram of a third sub-pixel SP3 may be substantially the same as the equivalent circuit diagram of the first sub-pixel SP1 described with reference to FIG. 3. Therefore, any repetitive detailed descriptions of the equivalent circuit diagram of the second sub-pixel SP2 and the equivalent circuit diagram of the third sub-pixel SP3 will be omitted in the present disclosure.

FIG. 4 is a schematic plan view illustrating an example of a display panel illustrated in FIG. 1.

Referring to FIG. 4, the display area DAA of the display panel 100 according to an embodiment includes a plurality of pixels PX arranged in a matrix form. The non-display area NDA of the display panel 100 according to an embodiment includes a scan driver 610, a light emitting driver 620, a data driver 700, a first distribution circuit 710, a second distribution circuit 720, a first pad portion PDA1, and a second pad portion PDA2.

The scan driver 610 may be disposed on a first side of the display area DAA, and the light emitting driver 620 may be disposed on a second side of the display area DAA. In an embodiment, for example, the scan driver 610 may be disposed on one side of the display area DAA in the first direction DR1, and the light emitting driver 620 may be disposed on the other side of the display area DAA in the first direction DR1. However, the embodiment of the present specification is not limited thereto, and the scan driver 610 and the light emitting driver 620 may be disposed on both the first side and the second side of the display area DAA.

The first pad portion PDA1 may include a plurality of first pads PD1 connected to pads or bumps of the circuit board 300 through a conductive adhesive member. The first pad portion PDA1 may be disposed on a third side of the display area DAA. In an embodiment, for example, the first pad portion PDA1 may be disposed on one side of the display area DAA in the second direction DR2. The first pad portion PDA1 may be disposed on the outside of the data driver 700 in the second direction DR2.

The second pad portion PDA2 may include a plurality of second pads PD2 corresponding to test pads for testing whether the display panel 100 is normally operating. The plurality of second pads PD2 may be connected to a jig or probe pin or to a test circuit board during the test process. The test circuit board may be a printed circuit board including or made of a rigid material or a flexible printed circuit board including or made of a flexible material.

The second pad portion PDA2 may be disposed on a fourth side of the display area DAA. In an embodiment, for example, the second pad portion PDA2 may be disposed on the other side of the display area DAA in the second direction DR2. The second pad portion PDA2 may be disposed on the outside of the second distribution circuit 720 in the second direction DR2.

The first distribution circuit 710 distributes data voltages applied through the first pad portion PDA1 to the plurality of data lines DL. In an embodiment, for example, the first distribution circuit 710 may distribute data voltages applied through one first pad PD1 of the first pad portion PDA1 to P data lines DL (P is a positive integer greater than or equal to 2), thereby reducing the number of first pads PD1. The first distribution circuit 710 may be disposed on a third side of the display area DAA of the display panel 100. In an embodiment, for example, the first distribution circuit 710 may be disposed on one side of the display area DAA in the second direction DR2.

The second distribution circuit 720 distributes signals applied through the second pad portion PDA2 to the scan driver 610, the light emitting driver 620, and the data lines DL. The second pad portion PDA2 and the second distribution circuit 720 may be components for testing the operation of each pixel PX of the display area DAA. The second distribution circuit 720 may be disposed on a fourth side of the display area DAA of the display panel 100. In an embodiment, for example, the second distribution circuit 720 may be disposed on the other side of the display area DAA in the second direction DR2.

A cathode connection portion CCA may be an area where a second electrode (CAT in FIG. 7) of a display element layer (EML in FIG. 7) is connected to the first driving voltage line VSL of the non-display area NDA. The cathode connection portion CCA may be disposed outside at least one side of the display area DAA. In an embodiment, for example, the cathode connection portion CCA may be disposed outside at least one of the left, right, upper, and lower sides of the display area DAA. Alternatively, the cathode connection portion CCA may be disposed to surround the display area DAA as illustrated in FIG. 4 to minimize a deviation in the first driving voltage VSS due to a voltage drop (IR drop) or voltage rising (IR rising) of the second electrode CAT in the display area DAA.

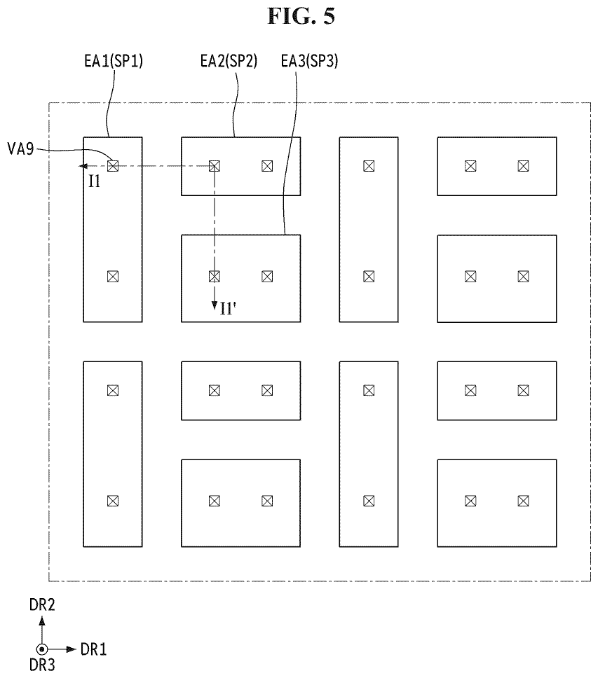

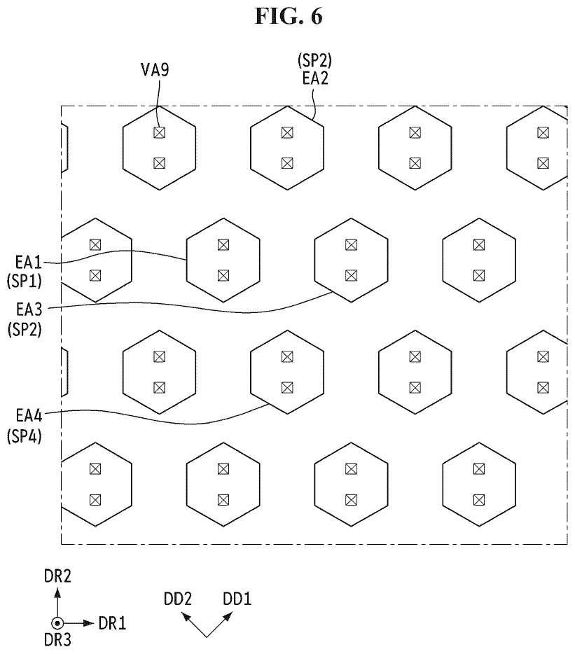

FIG. 5 is a schematic enlarged plan view illustrating an example of a display area of FIG. 4. FIG. 6 is a schematic enlarged plan view illustrating another example of the display area of FIG. 4.

Referring to FIGS. 5 and 6, each of the plurality of pixels PX includes a first light emitting area EA1, which is a light emitting area of the first sub-pixel SP1, a second light emitting area EA2, which is a light emitting area of the second sub-pixel SP2, and a third light emitting area EA3, which is a light emitting area of the third sub-pixel SP3.

The first light emitting area EA1, the second light emitting area EA2, and the third light emitting area EA3 may have a quadrangular or hexagonal planar shape as illustrated in FIGS. 5 and 6, but the embodiment of the present specification is not limited thereto. The first light emitting area EA1, the second light emitting area EA2, and the third light emitting area EA3 have a planar shape other than the quadrangle or hexagon, such as a polygon, circle, ellipse, or irregular shape.

In an embodiment, as illustrated in FIG. 5, in each of the plurality of pixels PX, the first light emitting area EA1 and the second light emitting area EA2 may be adjacent to each other in the first direction DR1. In addition, the first light emitting area EA1 and the third light emitting area EA3 may be adjacent to each other in the first direction DR1. In addition, the second light emitting area EA2 and the third light emitting area EA3 may be adjacent to each other in the second direction DR2. An area of the first light emitting area EA1, an area of the second light emitting area EA2, and an area of the third light emitting area EA3 may be different from each other.

Alternatively, as illustrated in FIG. 6, the light emitting areas EA1, EA2, EA3, and EA4 may have a hexagonal planar shape. In such an embodiment, the first light emitting area EA1 and the third light emitting area EA3 may be adjacent to each other in the first direction DR1, and the second light emitting area EA2 and a fourth light emitting area EA4 may be adjacent to each other in the second direction DR2. In addition, the first light emitting area EA1 and the second light emitting area EA2 may be adjacent to each other in a first diagonal direction DD1, and the second light emitting area EA2 and the third light emitting area EA3 may be adjacent to each other in a second diagonal direction DD2. In addition, the first light emitting area EA1 and the fourth light emitting area EA4 may be adjacent to each other in the second diagonal direction DD2, and the third light emitting area EA3 and the fourth light emitting area EA4 may be adjacent to each other in the first diagonal direction DD1. The first diagonal direction DD1, which is a direction between the first direction DR1 and the second direction DR2, may indicate a direction inclined by about 45 degrees compared to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. In an embodiment, for example, the blue wavelength band may indicate that a main peak wavelength of light is included in a wavelength band of about 370 nanometers (nm) to about 460 nm, the green wavelength band may indicate that a main peak wavelength of light is included in a wavelength band of about 480 nm to about 560 nm, and the red wavelength band may indicate that a main peak wavelength of light is included in a wavelength band of about 600 nm to about 750 nm.

Each of the plurality of pixels PX may include three light emitting areas EA1, EA2, and EA3 as illustrated in FIG. 5 or may include four light emitting areas EA1, EA2, EA3, and EA4 as illustrated in FIG. 6. In such an embodiment, the fourth light emitting area EA4 may emit a same second light as the second light emitting area EA2, but the embodiment of the present specification is not limited thereto.

The light emitting areas of the plurality of pixels PX may be disposed in a stripe structure in which the light-emitting areas are arranged in the first direction DR1, a PenTile® structure in which the light emitting areas EA1, EA2, EA3, and EA4 are arranged in a rhombus shape as illustrated in FIG. 6, or a hexagonal structure in which the light emitting regions are arranged in a hexagonal shape.

FIG. 7 is a schematic cross-sectional view illustrating an example of the display panel taken along line I1-I1′ of FIG. 5.

Referring to FIG. 7, an embodiment of the display panel 100 includes a semiconductor backplane SBP, a light emitting element backplane EBP, a display element layer EML, an encapsulation layer TFE, an optical layer OPL, a cover layer CVL, and a polarizing plate POL.

The semiconductor backplane SBP includes a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may correspond to the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with first-type impurities. A plurality of well areas WA may be disposed on an upper surface of the semiconductor substrate SSUB. The plurality of well areas WA may be areas doped with second-type impurities. The second-type impurity may be different from the first-type impurity described above. In an embodiment, for example, where the first-type impurity is a p-type impurity, the second-type impurity may be an n-type impurity. In another embodiment, where the first-type impurity is an n-type impurity, the second-type impurity may be a p-type impurity.

Each of the plurality of well areas WA includes a source area SA corresponding to a source electrode of the pixel transistor PTR, a drain area DA corresponding to a drain electrode thereof, and a channel area CH disposed between the source area SA and the drain area DA.

A lower insulating film BINS may be disposed between the gate electrode GE and the well area WA. A side insulating film SINS may be disposed on a side surface of the gate electrode GE. The side insulating film SINS may be disposed on the lower insulating film BINS.

Each of the source area SA and the drain area DA may be an area doped with first-type impurities. A gate electrode GE of the pixel transistor PTR may overlap the well area WA in the third direction DR3, which is a thickness direction of the semiconductor substrate SSUB. The channel area CH may overlap the gate electrode GE in the third direction DR3. The source area SA may be disposed on one side of the gate electrode GE, and the drain area DA may be disposed on the other side of the gate electrode GE.

Each of the plurality of well areas WA further includes a first low-concentration impurity area LDD1 disposed between the channel area CH and the source area SA and a second low-concentration impurity area LDD2 disposed between the channel area CH and the drain area DA. The first low-concentration impurity area LDD1 may be an area having an impurity concentration lower than that of the source area SA due to the lower insulating film BINS. The second low-concentration impurity area LDD2 may be an area having an impurity concentration lower than that of the drain area DA due to the lower insulating film BINS. A distance between the source area SA and the drain area DA may be increased by the first low-concentration impurity area LDD1 and the second low-concentration impurity area LDD2, which may increase a length of the channel area CH of each pixel transistor PTR.

A first semiconductor insulating film SINS1 may be disposed on the semiconductor substrate SSUB. A semiconductor insulating film SINS2 may be disposed on the first semiconductor insulating film SINS1.

A plurality of contact terminals CTE may be disposed on the second semiconductor insulating film SINS2. Each of the plurality of contact terminals CTE may be connected to a corresponding one of the gate electrode GE, the source area SA, and the drain area DA of each of the plurality of pixel transistors PTR through a hole defined through the first semiconductor insulating film SINS1 and the second semiconductor insulating film SINS2. The plurality of contact terminals CTE may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof.

A third semiconductor insulating film SINS3 may be disposed on a side surface of each of the plurality of contact terminals CTE. An upper surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be formed of (or defined by) an inorganic film including at least one selected from silicon nitride carbon (SiCN) or silicon oxide (SiOx), but the embodiment of the present specification is not limited thereto.

In an embodiment, the semiconductor substrate SSUB may be replaced with a glass substrate or a polymer resin substrate such as polyimide. In such an embodiment, thin film transistors may be disposed on the glass substrate or the polymer resin substrate. The glass substrate may be a rigid substrate that is not bent, and the polymer resin substrate may be a flexible substrate that may be bent or curved.

The light emitting element backplane EBP includes a plurality of conductive layers ML1 to ML8, a plurality of vias VA1 to VA9, and a plurality of insulating films INS1 to INS11. In addition, the light emitting element backplane EBP includes a plurality of insulating films INS1 to INS9 disposed between the first to eighth conductive layers ML1 to ML8.

The first to eighth insulating films INS1 to INS8 serve to insulate the first to eighth conductive layers ML1 to ML8. The first to eighth conductive layers ML1 to ML8 serve to implement the circuit of the first sub-pixel SP1 illustrated in FIG. 4 by connecting the plurality of contact terminals CTE exposed from the semiconductor backplane SBP.

In an embodiment, for example, only the first to sixth transistors T1 to T6 are formed on the semiconductor backplane SBP, and the first to sixth transistors T1 to T6 and the first and second capacitors C1 and C2 are connected through the first to eighth conductive layers ML1 to ML8. In addition, the drain area corresponding to the drain electrode of the fourth transistor T4, the source area corresponding to the source electrode of the fifth transistor T5, and the first electrode AND of the light emitting element LE are also connected through the first to eighth conductive layers ML1 to ML8.

The first to eighth conductive layers ML1 to ML8 and the first to eighth vias VA1 to VA8 may be formed of substantially a same material as each other. The first to eighth conductive layers ML1 to ML8 and the first to eighth vias VA1 to VA8 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof. The first to eighth vias VA1 to VA8 may be formed of substantially a same material as each other. The first to eighth insulating films INS1 to INS8 may be formed of an inorganic film including silicon oxide (SiOₓ), but the embodiment of the present specification is not limited thereto.

A ninth insulating film INS9 may be disposed on the eighth insulating film INS8 and the eighth conductive layer ML8. The ninth insulating film INS9 may be formed of an inorganic film including silicon oxide (SiOₓ), but the embodiment of the present specification is not limited thereto.

Each of the ninth vias VA9 may be connected to the eighth conductive layer ML8 exposed by penetrating or extending through the ninth insulating film INS9. The ninth vias VA9 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof.

The display element layer EML may be disposed on the light emitting element backplane EBP. The display element layer EML may include tenth and eleventh insulating films INS10 and INS11, a reflective electrode RL, first electrodes AND, a light emitting stack IL, a second electrode CAT, a pixel defining film PDL, and a plurality of trenches TRC.

The reflective electrode RL may be disposed on the ninth insulating film INS9. The reflective electrode RL may include at least one or more reflective electrodes RL1, RL2, RL3, and RLA. In an embodiment, for example, the reflective electrode RL may include first to fourth reflective electrodes RL1, RL2, RL3, and RLA as illustrated in FIG. 7.

The first reflective electrodes RL1 may be disposed on the ninth insulating film INS9 and may be connected to the ninth via VA9. Each of second reflective electrodes RL2 may be disposed on the first reflective electrode RL1 corresponding thereto. Each of third reflective electrodes RL3 may be disposed on the second reflective electrode RL2 corresponding thereto. Each of fourth reflective electrodes RL4 may be disposed on the third reflective electrode RL3 corresponding thereto.

Since the second reflective electrode RL2 may be an electrode that substantially reflects light from the light emitting elements, a thickness of the second reflective electrode RL2 may be greater than a thickness of the first reflective electrode RL1, a thickness of the third reflective electrode RL3, and a thickness of the fourth reflective electrode RL4.

The first reflective electrodes RL1 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof. In an embodiment, for example, the first reflective electrodes RL1 may include titanium nitride (TiN), the second reflective electrodes RL2 may include aluminum (Al), the third reflective electrodes RL3 may include titanium nitride (TiN), and the fourth reflective electrodes RL4 may include titanium (Ti).

A tenth interlayer insulating film INS10 may be disposed on the ninth interlayer insulating film INS9. The tenth interlayer insulating film INS10 may be disposed between the reflective electrodes RL adjacent to each other. The tenth interlayer insulating film INS10 may be a film for planarizing a level difference caused by the reflective electrodes RL. The eleventh interlayer insulating film INS11 may be disposed on the tenth interlayer insulating film INS10 and the reflective electrode RL.

The tenth interlayer insulating film INS10 and the eleventh interlayer insulating film INS11 may be formed of or defined by an inorganic film including silicon oxide (SiOx), but the embodiment of the present specification is not limited thereto.

The eleventh interlayer insulating film INS11 may be an optical auxiliary layer for adjusting a resonance distance of light emitted from the light emitting stack IL in at least one sub-pixel of the first sub-pixel SP1, the second sub-pixel SP2, and the third sub-pixel SP3. A thickness of the eleventh interlayer insulating film INS11 in the first sub-pixel SP1, the second sub-pixel SP2, and the third sub-pixel SP3 may be different from each other. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set in each of the first sub-pixel SP1, the second sub-pixel SP2, and the third sub-pixel SP3.

In an embodiment, for example, as illustrated in FIG. 7, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In such an embodiment, a distance between the first electrode AND and the reflective electrode RL in the first sub-pixel SP1 may be greater than a distance between the first electrode AND and the reflective electrode RL in the second sub-pixel SP2. In addition, the distance between the first electrode AND and the reflective electrode RL in the second sub-pixel SP2 may be greater than a distance between the first electrode AND and the reflective electrode RL in the third sub-pixel SP3.

Each of the tenth vias VA10 may be connected to the fourth reflective electrodes RL4 exposed by penetrating or extending through the eleventh interlayer insulating film INS11. The tenth vias VA10 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof. A thickness of the tenth via VA10 in the first sub-pixel SP1 may be greater than a thickness of the tenth via VA10 in the second sub-pixel SP2, and the thickness of the tenth via VA10 in the second sub-pixel SP2 may be greater than a thickness of the tenth via VA10 in the third sub-pixel SP3.

The first electrode AND of each of the light emitting elements LE may be disposed on the eleventh interlayer insulating film INS11 and may be connected to the tenth via VA10. The first electrode AND of each of the light emitting elements LE may be connected to the drain area DA or the source area SA of the pixel transistor PTR through the tenth via VA10, the reflective electrode RL, the first to ninth vias VA1 to VA9, the first to eighth conductive layers ML1 to ML8, and the contact terminal CTE. The first electrode AND of each of the light emitting elements LE may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof. In an embodiment, for example, the first electrode AND of each of the light emitting elements LE may be formed of titanium nitride (TiN).

The pixel defining film PDL may be disposed on a partial area of the first electrode AND of each of the light emitting elements LE. The pixel defining film PDL may cover an edge of the first electrode AND of each of the light emitting elements LE. The pixel defining film PDL may partition the first light emitting areas EA1, the second light emitting areas EA2, and the third light emitting areas EA3. Each of the first light emitting area EA1, the second light emitting area EA2, and the third light emitting area EA3 may be an area in which the light emitting element LE including the first electrode AND, the light emitting stack IL, and the second electrode CAT is disposed.

The first light emitting area EA1 may be defined as an area in which the first electrode AND, the light emitting stack IL, and the second electrode CAT are sequentially stacked in the first sub-pixel SP1 to emit light. The second light emitting area EA2 may be defined as an area in which the first electrode AND, the light emitting stack IL, and the second electrode CAT are sequentially stacked in the second sub-pixel SP2 to emit light. The third light emitting area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of an inorganic film including silicon oxide (SiOₓ). Alternatively, the first pixel defining film PDL1 and the third pixel defining film PDL3 are formed of an inorganic film including silicon nitride (SiNₓ), while the second pixel defining film PDL2 may be formed of an inorganic film including silicon oxide (SiOₓ). Each of a thickness of the first pixel defining film PDL1, a thickness of the second pixel defining film PDL2, and a thickness of the third pixel defining film PDL3 may be about 500 angstrom (Å).

In order to effectively prevent the first encapsulation inorganic film TFE1 from being disconnected due to the step coverage, the first pixel defining film PDL1, the second pixel defining film PDL2, and the third pixel defining film PDL3 may have a cross-sectional structure with a step-shaped level difference. The step coverage refers to a ratio of the extent to which a thin film is applied to an inclined portion relative to the extent to which a thin film is applied to a flat portion. As the step coverage is low, the possibility of the thin film disconnected at the inclined portion may increase.

Each of the plurality of trenches TRC may be defined through the first pixel defining film PDL1, the second pixel defining film PDL2, and the third pixel defining film PDL3. In each of the plurality of trenches TRC, at least a portion of the eleventh interlayer insulating film INS11 may have a recessed shape.

At least one trench TRC may be disposed between the sub-pixels SP1, SP2, and SP3 adjacent to each other. FIG. 7 illustrates an embodiment where two trenches TRC are disposed between the sub-pixels SP1, SP2, and SP3 adjacent to each other, but the embodiment of the present specification is not limited thereto.

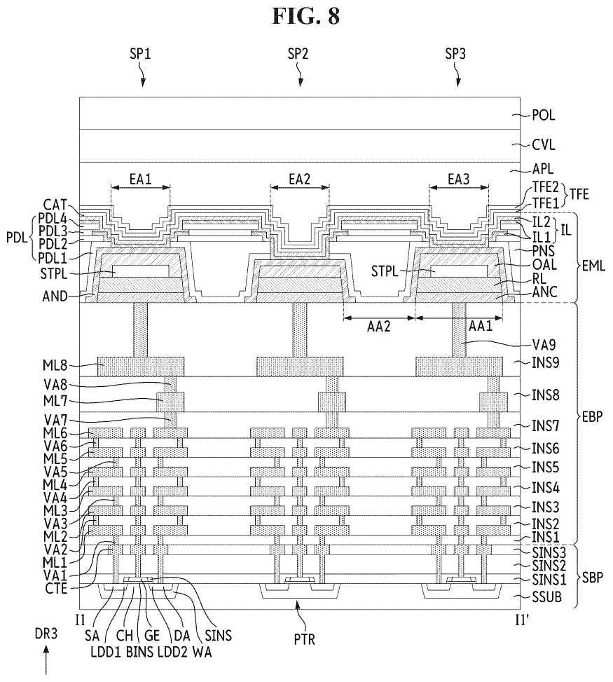

The light emitting stack IL may include a plurality of stack layers IL1, IL2, and IL3. FIG. 7 illustrates an embodiment where the light emitting stack IL has a three-tandem structure including a first stack layer IL1, a second stack layer IL2, and a third stack layer IL3, but the embodiment of present specification is not limited thereto. In another embodiment, for example, the light emitting stack IL may have a two-tandem structure including two stack layers as illustrated in FIG. 8.

In the three-tandem structure, the light emitting stack IL may have a tandem structure including a plurality of stack layers IL1, IL2, and IL3 that emit different lights, respectively. In an embodiment, for example, the light emitting stack IL may include a first stack layer IL1 that emits light of a first color, a second stack layer IL2 that emits light of a second color, and a third stack layer IL3 that emits light of a third color. The first stack layer IL1, the second stack layer IL2, and the third stack layer IL3 may be sequentially stacked.

The first stack layer IL1 may have a structure in which a first hole transporting layer, a first light emitting layer emitting first light, and a first electron transporting layer are sequentially stacked. The second stack layer IL2 may have a structure in which a second hole transporting layer, a second light emitting layer emitting second light, and a second electron transporting layer are sequentially stacked. The third stack layer IL3 may have a structure in which a third hole transporting layer, a third organic light emitting layer emitting third light, and a third electron transporting layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an n-type charge generation layer that supplies electrons to the first stack layer IL1 and a p-type charge generation layer that supplies holes to the second stack layer IL2. The n-type charge generation layer may include a dopant of a metallic material.

A second charge generation layer for supplying charges to the third stack layer IL3 and supplying electrons to the second stack layer IL2 may be disposed between the second stack layer IL2 and the third stack layer IL3. The second charge generation layer may include an n-type charge generation layer that supplies electrons to the second stack layer IL2 and a p-type charge generation layer that supplies holes to the third stack layer IL3.

The first stack layer IL1 may be disposed on the first electrodes AND and the pixel defining film PDL, and in each of the trenches TRC, a residual film RIL disposed on a bottom surface of the trench TRC may include a same material as the first stack layer IL1. Due to the trench TRC, the first stack layer IL1 may be disconnected between the sub-pixels SP1, SP2, and SP3 adjacent to each other. The second stack layer IL2 may be disposed on the first stack layer IL1. Due to the trench TRC, the second stack layer IL2 may be disconnected between the sub-pixels SP1, SP2, and SP3 adjacent to each other. A cavity ESS or empty space may be disposed between the residual film RIL and the second stack layer IL2 in the trench TRC. The third stack layer IL3 may be disposed on the second stack layer IL2. The third stack layer IL3 may not be disconnected by the trench TRC and may be disposed to cover the second stack layer IL2 in each of the trenches TRC.

In the three-tandem structure, each of the plurality of trenches TRC may be a structure for disconnecting the first to third hole transporting layers, the first charge generation layer, and the second charge generation layer of the first to third stack layers IL1, IL2, and IL3 of the display element layer EML between the sub-pixels SP1, SP2, and SP3 adjacent to each other. In addition, in the two-tandem structure, each of the plurality of trenches TRC may be a structure for disconnecting the charge generation layer disposed between a lower stack layer and an upper stack layer and the lower stack layer.

In order to stably disconnect the first and second stack layers IL1 and IL2 of the display element layer EML between the sub-pixels SP1, SP2, and SP3 adjacent to each other, a height of each of the plurality of trenches TRC may be greater than a height of the pixel defining film PDL. The height of each of the plurality of trenches TRC indicates a length of each of the plurality of trenches TRC in the third direction DR3. The height of the pixel defining film PDL indicates a length of the pixel defining film PDL in the third direction DR3. In order to disconnect the hole transporting layers and the charge generation layers of the light emitting stack IL of the display element layer EML between the sub-pixels SP1, SP2, and SP3 adjacent to each other, other structures may be present instead of the trench TRC. In an embodiment, for example, instead of the trench TRC, a partition wall having a reverse tapered shape may be disposed on the pixel defining film PDL.

In addition, FIG. 7 illustrates an embodiment where the light emitting stack IL that emits light is disposed in all of the first light emitting area EA1, the second light emitting area EA2, and the third light emitting area EA3, but the embodiment of the present specification is not limited thereto. In another embodiment, for example, instead of the light emitting stack IL, the first light emitting stack IL1 may be disposed in the first light emitting area EA1 and may not be disposed in the second light emitting area EA2 and the third light emitting area EA3. In addition, the second light emitting layer may be disposed in the second light emitting area EA2 and may not be disposed in the first light emitting area EA1 and the third light emitting area EA3. In addition, the third light emitting layer may be disposed in the third light emitting area EA3 and may not be disposed in the first light emitting area EA1 and the second light emitting area EA2. In this case, first to third color filters CF1, CF2, and CF3 of the optical layer OPL may be omitted.

The second electrode CAT may be disposed on the light emitting stack IL. The second electrode CAT may be disposed on the third stack layer IL3 in each of the plurality of trenches TRC. The second electrode CAT may include or be formed of a transparent conductive material (TCO) such as ITO or IZO capable of transmitting light, or a semi-transmissive conductive material such as magnesium (Mg), silver (Ag), or an alloy of magnesium (Mg) and silver (Ag). In an embodiment where the second electrode CAT is formed of a semi-transmissive conductive material, light emission efficiency may be increased in each of the first to third sub-pixels SP1, SP2, and SP3 by micro cavities.

The encapsulation layer TFE may be disposed on the display element layer EML. The encapsulation layer TFE may include one or more inorganic films TFE1 and TFE3 to prevent oxygen or moisture from permeating into the display element layer EML. In an embodiment, for example, a first encapsulation inorganic film TFE1 may be disposed on the second electrode CAT, and a second encapsulation inorganic film TFE3 may be disposed on the first encapsulation inorganic film TFE1. The first encapsulation inorganic film TFE1 and the second encapsulation inorganic film TFE3 may be formed as or defined by multi-films in which one or more inorganic films of a silicon nitride layer (SiNx), a silicon oxynitride layer (SiON), a silicon oxide layer (SiOx), a titanium oxide layer (TiOx), and an aluminum oxide layer (AlOx) are alternately stacked.

In addition, the encapsulation layer TFE may include at least one organic film TFE2 to protect the display element layer EML from foreign substances such as dust. In an embodiment, for example, the encapsulation organic film TFE2 may be disposed between the first encapsulation inorganic film TFE1 and the second encapsulation inorganic film TFE3. The encapsulation organic film TFE2 may be a monomer. Alternatively, the encapsulation organic film TFE2 may be an organic film made of an acrylic resin, an epoxy resin, a phenolic resin, a polyamide resin, or a polyimide resin.

An adhesive layer ADL may be a layer for adhering the encapsulation layer TFE and the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be disposed on the adhesive layer ADL.

The first color filter CF1 may overlap the first light emitting area EA1 of the first sub-pixel SP1. The first color filter CF1 may transmit light of a first color, that is, light in a blue wavelength band. The red wavelength band may be about 370 nm to about 460 nm. Therefore, the first color filter CF1 may transmit light of a first color among light emitted from the first light emitting area EA1.

The second color filter CF2 may overlap the second light emitting area EA2 of the second sub-pixel SP2. The second color filter CF2 may transmit light of a second color, that is, light in a green wavelength band. The green wavelength band may be about 480 nm to about 560 nm. Therefore, the second color filter CF2 may transmit light of a second color among light emitted from the second light emitting area EA2.

The third color filter CF3 may overlap the third light emitting area EA3 of the third sub-pixel SP3. The third color filter CF3 may transmit light of a third color, that is, light in a red wavelength band. The red wavelength band may be about 600 nm to about 750 nm. Therefore, the third color filter CF3 may transmit light of a third color among light emitted from the third light emitting area EA3.

Each of the plurality of lenses LNS may be disposed on each of the first color filter CF1, the second color filter CF2, and the third color filter CF3. Each of the plurality of lenses LNS may be a structure for increasing a ratio of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index so that light travels in the third direction DR3 at an interface between the plurality of lenses LNS and the filling layer FIL. In addition, the filling layer FIL may be a planarization layer. The filling layer FIL may be an organic film including or made of an acryl resin, an epoxy resin, a phenolic resin, a polyamide resin, or a polyimide resin.

The cover layer CVL may be disposed on the filling layer FIL. The cover layer CVL may be a glass substrate or a polymer resin such as resin. In an embodiment where the cover layer CVL is a glass substrate, the cover layer CVL may be attached onto the filling layer FIL. In this case, the filling layer FIL may serve to adhere the cover layer CVL. In an embodiment where the cover layer CVL is a glass substrate, the cover layer CVL may serve as an encapsulation substrate. When the cover layer CVL is a polymer resin such as resin, the cover layer CVL may be directly applied on the filling layer FIL.

The polarizing plate may be disposed on one surface of the cover layer CVL. The polarizing plate may be a structure for preventing deterioration in visibility due to reflection of external light. The polarizing plate may include a linear polarizing plate and a phase retardation film. In an embodiment, for example, the phase retardation film may be a λ/4 (quarter-wave) plate, but the embodiment of the present specification is not limited thereto. However, when deterioration in visibility due to reflection of external light is sufficiently improved by the first to third color filters CF1, CF2, and CF3, the polarizing plate may also be omitted.

FIG. 8 is a schematic cross-sectional view illustrating another example of the display panel taken along line I1-I1′ of FIG. 5.

The embodiment of FIG. 8 is substantially the same as the embodiment of FIG. 7 except that the first electrode AND of each of the light emitting elements LE is electrically connected by being in contact with a side surface of a connection electrode ANC connected to the eighth conductive layer ML8. In addition, the embodiment of FIG. 8 is substantially the same as the embodiment of FIG. 7 except that the trench TRC is omitted, and instead, a third pixel defining film PDL3 and a fourth pixel defining film PDL4 have a cross-sectional structure in a shape of an caves or a mushroom shape. In description of the embodiment of FIG. 8, any repetitive detailed description of the same or like element as those of the embodiment of FIG. 7 described above will be omitted.

Referring to FIG. 8, a plurality of connection electrodes ANC may be respectively disposed on first portions AA1 of the ninth insulating film INS9. Each of the plurality of connection electrodes ANC may be disposed on the first portion AA1 of the ninth insulating film INS9 corresponding thereto. The plurality of connection electrodes ANC may include or be formed of an alloy including at least one selected from copper (Cu), aluminum (Al), tungsten (W), molybdenum (Mo), chromium (Cr), gold (Au), titanium (Ti), nickel (Ni), and neodymium (Nd), or transparent conductive oxide. For example, the plurality of connection electrodes ANC may include titanium (Ti), titanium nitride (TiN), indium tin oxide (ITO), or indium zinc oxide (IZO), but the embodiment of the present specification is not limited thereto.

A plurality of reflective electrodes RL may be respectively disposed on the plurality of connection electrodes ANC. Each of the plurality of reflective electrodes RL may be disposed on the connection electrode ANC corresponding thereto. The plurality of reflective electrodes RL may include or be formed at least one selected from copper (Cu), aluminum (Al), tungsten (W), molybdenum (Mo), chromium (Cr), gold (Au), titanium (Ti), nickel (Ni), and neodymium (Nd), or an alloy including any one thereof. In an embodiment, for example, each of the plurality of reflective electrodes RL may include aluminum (Al) having high reflectivity.

A plurality of optical auxiliary films OAL may be respectively disposed on the plurality of reflective electrodes RL. Each of plurality of optical auxiliary films OAL may be disposed on the reflective electrode RL corresponding thereto. The plurality of optical auxiliary films OAL may be formed of an inorganic film including silicon oxide (SiOₓ), but the embodiment of the present specification is not limited thereto.

A step layer STPL may be disposed on the reflective electrode RL in each of the first light emitting area EA1 and the third light emitting area EA3, and the optical auxiliary film OAL may be disposed on the step layer STPL. In the second light emitting area EA2, only the optical auxiliary film OAL may be disposed on the reflective electrode RL. The thicknesses of the optical auxiliary film OAL in the first light emitting area EA1, the second light emitting area EA2, and the third light emitting area EA3 may be substantially the same.

Due to the step layer STPL, a distance between the reflective electrode RL and the first electrode AND in the first light emitting area EA1 and the third light emitting area EA3 may be greater than a distance between the reflective electrode RL and the first electrode AND in the second light emitting area EA2. The thickness of the step layer STPL and the thickness of the optical auxiliary film OAL may be set by considering the wavelength and resonance distance of light emitted from the first stack layer IL1 of the light emitting stack IL and the wavelength and resonance distance of light emitted from the second stack layer IL2 thereof.

Each of the light emitting elements LE may include a first electrode AND, a light emitting stack IL, and a second electrode CAT.

The first electrode AND of each of the light emitting elements LE may be disposed on the optical auxiliary film OAL corresponding thereto. Since the connection electrode ANC, the reflective electrode RL, and the optical auxiliary film OAL are sequentially stacked, the first electrode AND of each of the light emitting elements LE may be disposed on upper and side surfaces of the optical auxiliary film OAL, a side surface of the reflective electrode RL, and a side surface of the connection electrode ANC. As a result, the first electrode AND of each of the light emitting elements LE may be electrically connected by being in contact with the side surface of the reflective electrode RL and the side surface of the connection electrode ANC. Therefore, since the mask process may be reduced compared to when the first electrode AND of each of the light emitting elements LE is connected to the exposed reflective electrode RL through a through hole defined through the optical auxiliary film OAL, manufacturing costs may be reduced and manufacturing efficiency may be increased.

The first electrode AND of each of the light emitting elements LE may be connected to the drain area DA or the source area SA of the pixel transistor PTR through the connection electrode ANC, the first to ninth vias VA1 to VA9, the first to eighth conductive layers ML1 to ML8, and the contact terminal CTE.

The ninth insulating film INS9 may include a first portion AA1 that overlaps the connection electrode ANC in the third direction DR3 and a second portion AA2 that does not overlap the connection electrode ANC in the third direction DR3. A thickness of the first portion AA1 and a thickness of the second portion AA2 of the ninth insulating film INS9 may be substantially the same as each other.

Alternatively, the thickness of the first portion AA1 of the ninth insulating film INS9 may be greater than the thickness of the second portion AA2. In such an embodiment, a side surface of the first portion AA1 of the ninth insulating film INS9 may be exposed, and the first electrode AND of each of the light emitting elements LE may be disposed on the exposed side surface of the first portion AA1 of the ninth insulating film INS9.

The first electrode AND of each of the light emitting elements LE may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof, or a transparent conductive oxide. For example, the first electrode AND of each of light emitting elements LE may include titanium nitride (TiN), indium tin oxide (ITO), or indium zinc oxide (IZO), but the embodiment of the present specification is not limited thereto.

The pixel defining film PDL may be disposed on a partial area of the first electrode AND of each of the light emitting elements LE. The pixel defining film PDL may cover an edge of the first electrode AND of each of the light emitting elements LE. The pixel defining film PDL may partition the first light emitting areas EA1, the second light emitting areas EA2, and the third light emitting areas EA3.

The pixel defining film PDL may include first to fourth pixel defining films PDL1, PDL2, PDL3, and PDL4.

The first pixel defining film PDL1 may be disposed on the first electrode AND of each of the light emitting elements LE. Specifically, the first pixel defining film PDL1 may cover a portion of an upper surface of the first electrode AND disposed on the optical auxiliary film OAL. In addition, the first pixel defining film PDL1 may cover the first electrode AND disposed on the side surface of the connection electrode ANC, the side surface of the reflective electrode RL, and the side surface of the optical auxiliary film OAL. The first pixel defining film PDL1 may be disposed on an upper surface of the second portion AA2 of the ninth insulating film INS9.

A planarization film PNS is a film for planarizing the steps caused by the connection electrode ANC, the reflective electrode RL, and the optical auxiliary film OAL.

The planarization film PNS may be disposed on the first pixel defining film PDL1 that covers the first electrode AND disposed on the side surface of the connection electrode ANC, the side surface of the reflective electrode RL, and the side surface of the optical auxiliary film OAL. The planarization film PNS may be disposed on the first pixel defining film PDL1 disposed on the second portion AA2 of the ninth insulating film INS9.

The planarization film PNS may be disposed between the connection electrodes ANC adjacent to each other in the first direction DR1 or the second direction DR2. The planarization film PNS may be disposed between the reflective electrodes RL adjacent to each other in the first direction DR1 or the second direction DR2. The planarization film PNS may be disposed between the optical auxiliary films OAL adjacent to each other in the first direction DR1 or the second direction DR2.

While there is no step layer STPL in the second light emitting area EA2, there is a step layer STPL in each of the first light emitting area EA1 and the third light emitting area EA3. As a result, the height of the connection electrode ANC, the reflective electrode RL, and the optical auxiliary film OAL in the second light emitting area EA2 may be smaller than the height of the connection electrode ANC, the reflective electrode RL, the step layer STPL, and the optical auxiliary film OAL in each of the first light emitting area EA1 and the third light emitting area EA3. Therefore, the planarization film PNS may cover the upper surface of the first pixel defining film PDL1 disposed on the upper surface of the first electrode AND disposed in the second light emitting area EA2.

In comparison, an upper surface of the planarization film PNS may be flatly connected to the upper surface of the first electrode AND disposed in the first light emitting area EA1 and the third light emitting area EA3. That is, the planarization film PNS may not cover the upper surface of the first pixel defining film PDL1 disposed on the upper surface of the first electrode AND disposed in each of the first light emitting area EA1 and the third light emitting area EA3.

The second pixel defining film PDL2 may be disposed on the first pixel defining film PDL1 and the planarization film PNS, the third pixel defining film PDL3 may be disposed on the second pixel defining film PDL2, and the fourth pixel defining film PDL4 may be disposed on the third pixel defining film PDL3. The first pixel defining film PDL1 and the third pixel defining film PDL3 are formed of an inorganic film o including f silicon nitride (SiNx), while the second pixel defining film PDL2, the fourth pixel defining film PDL4, and the planarization film PNS may be formed of an inorganic film including silicon oxide (SiOx). As the first pixel defining film PDL1 is formed of a different material from the planarization film PNS, the first pixel defining film PDL1 may serve as a stopper in a process of chemically and mechanically polishing the planarization film PNS.

When the planarization film PNS and the second pixel defining film PDL2 are identically formed of an inorganic film including silicon oxide (SiOx), the planarization film PNS and the second pixel defining film PDL2 may be formed as a single film.

Since a length of the third pixel defining film PDL3 in one direction is smaller than a length of the fourth pixel defining film PDL4 in one direction, a lower surface of the fourth pixel defining film PDL4 may be exposed without being covered by the third pixel defining film PDL3. That is, the third pixel defining film PDL3 and the fourth pixel defining film PDL4 may have a cross-sectional structure in a shape of an caves or a mushroom shape.

The light emitting stack IL may be disposed on the first electrodes AND and the pixel defining film PDL. The light emitting stack IL may include a first stack layer IL1 and a second stack layer IL2 that emit different lights. When the light emitting stack IL has a two-tandem structure, one of the first stack layer IL1 and the second stack layer IL2 may emit light including a wavelength range of one of the first light, the second light, and the third light, and the other thereof may emit light that includes the wavelength ranges of the other two lights. For example, the first stack layer IL1 may emit light that includes a wavelength range of the first light and a wavelength range of the third light, and the second stack layer IL2 may emit light that includes a wavelength range of the second light. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be disposed between the first stack layer IL1 and the second stack layer IL2. The charge generation layer may include an n-type charge generation layer that supplies electrons to the first stack layer IL1 and a p-type charge generation layer that supplies holes to the second stack layer IL2. The n-type charge generation layer may include a dopant of a metallic material.

Since the first stack layer IL1 is not formed on the exposed lower surface of the fourth pixel defining film PDL4 that is not covered by the third pixel defining film PDL3, the first stack layer IL1 may be disconnected by the cross-sectional structure in the shape of an eaves or the mushroom shape by the third pixel defining film PDL3 and the fourth pixel defining film PDL4. In this case, the first hole transporting layer of the first stack layer IL1 and the charge generation layer CGL disposed between the first stack layer IL1 and the second stack layer IL2 may also be disconnected. In addition, FIG. 8 illustrates an embodiment where the second stack layer IL2 is connected without being disconnected, but the second hole transporting layer of the second stack layer IL2 may be disconnected, and the second electron transporting layer of the second stack layer IL2 may be connected without being disconnected. Therefore, it is possible to effectively prevent leakage current from flowing between the light emitting areas EA1, EA2, and EA3 adjacent to each other through the first hole transporting layer of the first stack layer IL1, the second hole transporting layer of the second stack layer IL2, and the charge generation layer CGL. Therefore, it is possible to effectively prevent the light emitting stacks IL in the light emitting areas EA1, EA2, and EA3 adjacent to each other from being affected by the current and emitting light other than the originally intended light.

FIG. 8 illustrates an embodiment having the two-tandem structure in which the light emitting stack IL includes two stack layers IL1 and IL2, but the embodiment of the present specification is not limited thereto. For example, the light emitting stack IL may have a three-tandem structure including three stack layers as illustrated in FIG. 7. In such an embodiment, by adjusting the height of the third pixel defining film PDL3, the charge generation layer between the first stack layer IL1 and the second stack layer IL2, and the charge generation layer between the second stack layer IL2 and the third stack layer IL3 may be designed to be disconnected. In another embodiment, as illustrated in FIG. 7, a trench defined through the first pixel defining film PDL1, planarization film PNS, the second pixel defining film PDL2, and the third pixel defining film PDL3 may be provided. In such an embodiment, the trench TRC may be defined through at least a portion of the ninth insulating film INS9, but the embodiment of the present specification is not limited thereto.

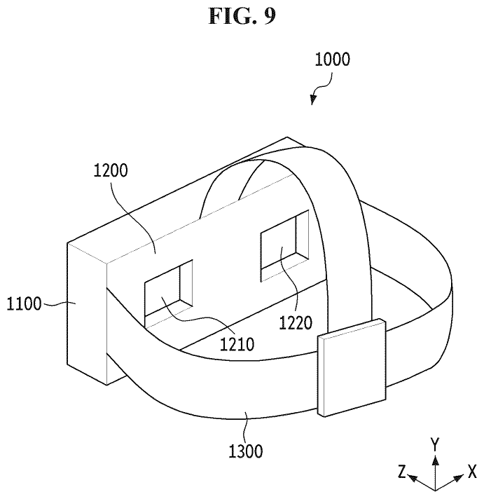

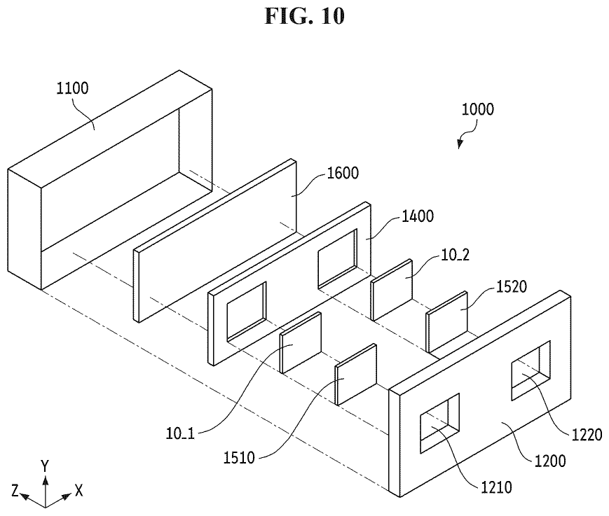

FIG. 9 is a perspective view illustrating an example of a head mounted display device. FIG. 10 is an exploded perspective view for describing the head mounted display device of FIG. 9.

Referring to FIGS. 9 and 10, a head mounted display device 1000 according to an embodiment includes a first display device 10_1, a second display device 10_2, a display device accommodating portion 1100, an accommodating portion cover 1200, a first eyepiece 1210, a second eyepiece 1220, a head mounting band 1300, a middle frame 1400, a first optical member 1510, a second optical member 1520, and a control circuit board 1600.

The first display device 10_1 provides an image to a user's left eye, and the second display device 10_2 provides an image to a user's right eye. Since each of the first display device 10_1 and the second display device 10_2 is substantially the same as the display device 10 described with reference to FIGS. 1 to 8, any repetitive descriptions of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and may be disposed between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device accommodating portion 1100. The control circuit board 1600 may be connected to the first display device 10_1 and the second display device 10_2 through a connector. The control circuit board 1600 may convert an image source input from the outside into digital video data DATA, and may transmit the digital video data DATA to the first display device 10_1 and the second display device 10_2 through the connector.

The control circuit board 1600 may transmit digital video data DATA corresponding to a left eye image optimized for the user's left eye to the first display device 10_1, and may transmit digital video data DATA corresponding to a right eye image optimized for the user's right eye to the second display device 10_2. Alternatively, the control circuit board 1600 may transmit the same digital video data DATA to the first display device 10_1 and the second display device 10_2.

The display device accommodating portion 1100 serves to accommodate the first display device 10_1, the second display device 10_2, the middle frame 1400, the first optical member 1510, the second optical member 1520, and the control circuit board 1600. The accommodating portion cover 1200 is disposed to cover one opened surface of the display device accommodating portion 1100. The accommodating portion cover 1200 may include a first eyepiece 1210 where the user's left eye is disposed and a second eyepiece 1220 where the user's right eye is disposed. FIGS. 9 and 10 illustrate an embodiment where the first eyepiece 1210 and the second eyepiece 1220 are separately disposed, but the embodiment of the present specification is not limited thereto. The first eyepiece 1210 and the second eyepiece 1220 may be integrated into one.

The first eyepiece 1210 may be aligned with the first display device 10_1 and the first optical member 1510, and the second eyepiece 1220 may be aligned with the second display device 10_2 and the second optical member 1520. Therefore, the user may view an image of the first display device 10_1 magnified as a virtual image by the first optical member 1510 through the first eyepiece 1210, and may view an image of the second display device 10_2 magnified as a virtual image by the second optical member 1520 through the second eyepiece 1220.

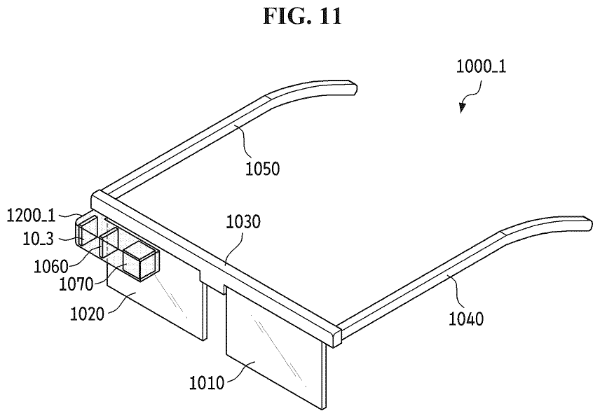

The head mounting band 1300 serves to fix the display device accommodating portion 1100 to a user's head such that the first eyepiece 1210 and the second eyepiece 1220 of the accommodating portion cover 1200 are disposed on the user's left and right eyes, respectively. In an embodiment where the display device accommodating portion 1100 is desired to be implemented in a lightweight and small size, the head mounted display device 1000 may include eyeglass frames as illustrated in FIG. 11 instead of the head mounting band 1300.

FIG. 11 is a perspective view illustrating another example of a head mounted display device.

Referring to FIG. 11, a head mounted display device 1000_1 according to an embodiment may be a glasses-type display device in which a display device accommodating portion 1200_1 is implemented in a lightweight and small size. The head mounted display device 1000_1 according to an embodiment may include a display device 10_3, a left eye lens 1010, a right eye lens 1020, a support frame 1030, eyeglass frame legs 1040 and 1050, an optical member 1060, a light path conversion member 1070, and a display device accommodating portion 1200_1.

The display device accommodating portion 1200_1 may accommodate the display device 10_3, the optical member 1060, and the light path conversion member 1070 therein. As an image displayed on the display device 10_3 is magnified by the optical member 1060 and a light path thereof is converted by the light path conversion member 1070, the image may be provided to the user's right eye through the right eye lens 1020. Accordingly, the user may view an augmented reality image in which a virtual image displayed on the display device 10_3 and a real image viewed through the right eye lens 1020 are combined through the right eye.

FIG. 11 illustrates an embodiment where the display device accommodating portion 1200_1 is disposed at a right distal end of the support frame 1030, but the embodiment of the present specification is not limited thereto. In an embodiment, for example, the display device accommodating portion 1200_1 may be disposed at a left distal end of the support frame 1030, and in this case, the image of the display device 10_3 may be provided to the user's left eye. Alternatively, the display device accommodating portions 1200_1 may be disposed at both the left and right distal ends of the support frame 1030. In this case, the user may view the image displayed on the display device 10_3 through both the user's left and right eyes.

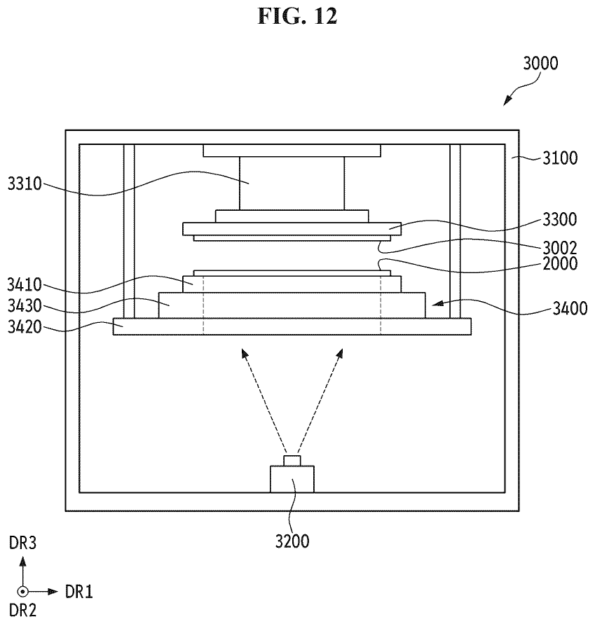

FIG. 12 is a schematic view illustrating a deposition device according to an embodiment.

Referring to FIG. 12, an embodiment of a deposition device 3000 may be used to form light emitting material layers on a backplane substrate 3002 in a process of manufacturing the display panel 100 (see FIG. 1). In an embodiment, for example, as illustrated in FIG. 7, a semiconductor backplane SBP and a light emitting element backplane EBP may be disposed on the backplane substrate 3002, and a reflective electrode layer RL and a tenth interlayer insulating film INS10 may be disposed on the light emitting element backplane EBP. An eleventh interlayer insulating film INS11 may be disposed on the tenth interlayer insulating film INS10, electrode patterns, for example, anode electrodes AND, may be disposed on the eleventh interlayer insulating film INS11, and the anode electrodes AND may be electrically connected to the reflective electrode layer RL through vias VA10. The deposition device 3000 may be used to form a light emitting stack IL on the electrode patterns.

The deposition device 3000 may include a deposition source 3200 for providing a vapor deposition material on the backplane substrate 3002, a deposition mask 2000 disposed on the deposition source 3200, and a substrate chuck 3300 that is disposed on the deposition mask 2000 and supports the backplane substrate 3002 so that the backplane substrate 3002 faces the deposition mask 2000. That is, the substrate chuck 3300 may support the backplane substrate 3002 in a way such that the front side of the backplane substrate 3002 faces downward, and may position the backplane substrate 3002 on the deposition mask 2000 to perform a deposition process. The substrate chuck 3300 may be supported by a support member 3310.

The deposition source 3200, the deposition mask 2000, and the substrate chuck 3300 may be disposed within a process chamber 3100. The process chamber 3100 may have an internal space defined therein, and a deposition process for forming a deposition material layer on the backplane substrate 3002 may be performed in the internal space of the process chamber 3100. Although not illustrated, the process chamber 3100 may be connected to a vacuum pump (not illustrated), and the internal space of the process chamber 3100 may be created into a vacuum atmosphere by the vacuum chamber. An opening (not illustrated) for the entry and exit of the backplane substrate 3002 and the deposition mask 2000 may be provided on one side wall of the process chamber 3100, and may be opened and closed by a gate valve (not illustrated).

A deposition material may be stored within the deposition source 3200. The deposition source 3200 may evaporate a deposition material such as an organic material, an inorganic material, a conductive material, etc. toward the backplane substrate 3002, and the evaporated deposition material may be deposited on the backplane substrate 3002 through the deposition mask 2000. In an embodiment, for example, the deposition source 3200 may evaporate an organic material for forming light emitting material layers on the backplane substrate 3002, and the evaporated organic material may be deposited on electrode patterns on the backplane substrate 3002 through the deposition mask 2000.

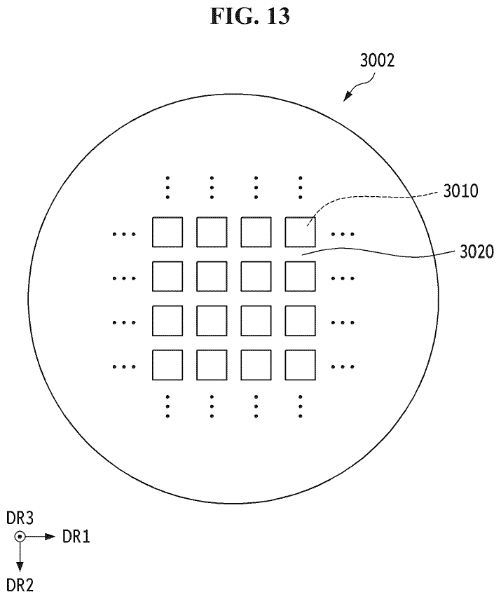

FIG. 13 is a schematic bottom view illustrating a backplane substrate illustrated in FIG. 12.

Referring to FIG. 13, the backplane substrate 3002 may include a plurality of display cell areas 3010 and a scribe lane 3020 area disposed between the display cell areas 3010. The display cell areas 3010 may be disposed or arranged in a matrix form along the first direction DR1 and the second direction DR2, as illustrated in FIG. 13, and each display cell area 3010 may be individualized as a display panel 100 (see FIG. 1) through a dicing process after the display manufacturing process is completed. For example, the display cell areas 3010 may be arranged in a matrix form along a first horizontal direction DR1 and a second horizontal direction DR2 perpendicular to the first horizontal direction DR1. The display cell areas 3010 may correspond to the number and arrangement of mask cell areas 2310 of the deposition mask 2000.

Each of the display cell areas 3010 may include a semiconductor backplane SBP, a light emitting element backplane EBP disposed on the semiconductor backplane SBP, a reflective electrode layer RL disposed on the light emitting element backplane EBP, and an eleventh interlayer insulating film INS11 disposed on the reflective electrode layer RL. In addition, each of the display cell areas 3010 may include a plurality of electrode patterns, for example, a plurality of anode electrodes AND, disposed on the eleventh interlayer insulating film INS11, and the anode electrodes AND may be connected to the reflective electrode layer RL through a plurality of vias VA10. In such an embodiment, the electrode patterns of the display cell areas 3010 may be disposed on the front surface of the backplane substrate 3002, and the substrate chuck 3300 may grip the rear surface of the backplane substrate 3002 in a way such that the electrode patterns of the display cell areas 3010 face downward, i.e., toward the deposition source 3200.

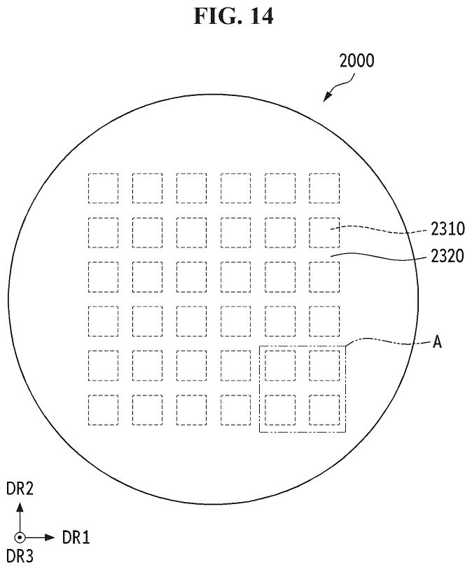

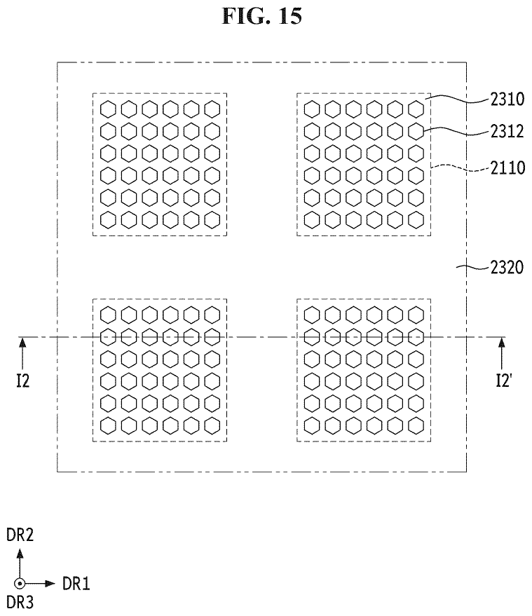

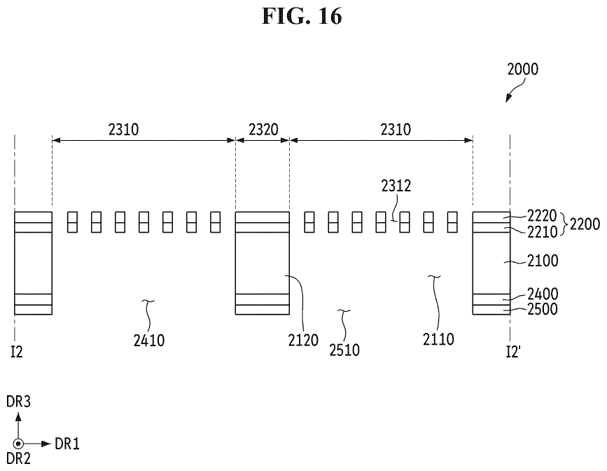

FIG. 14 is a schematic plan view illustrating a deposition mask according to an embodiment of the present disclosure. FIG. 15 is a schematic enlarged plan view illustrating mask cell areas illustrated in FIG. 14. FIG. 16 is a cross-sectional view taken along line I2-I2′ of FIG. 15.

Referring to FIGS. 14 to 16, the deposition mask 2000 according to an embodiment of the present disclosure may include a mask frame 2100, a membrane 2200, a first rear inorganic film layer 2400, and a second rear inorganic film layer 2500.

The mask frame 2100 may define cell openings 2110 and may include lip areas 2120 defining the cell openings 2110. The mask frame 2100 may be provided as or defined by a single crystal silicon substrate, and the cell openings 2110 may be formed through a wet etching process using tetramethyl ammonium hydroxide (TMAH) or potassium hydroxide (KOH). A crystal direction of the single crystal silicon substrate provided as the mask frame 2100 may be the third direction DR3.

The membrane 2200 may be disposed on the mask frame 2100. The membrane 2200 may include mask cell areas 2310 each corresponding to the display cell areas 3010 of the backplane substrate 3002 and a grid area 2320 excluding the mask cell areas 2310.

The mask cell areas 2310 may be disposed in a matrix form having a plurality of rows and a plurality of columns along the first direction DR1 and the second direction DR2, as illustrated in FIG. 14. In an embodiment, for example, the mask cell areas 2310 may be disposed in a matrix form along a first horizontal direction DR1 and a second horizontal direction DR2 perpendicular to the first horizontal direction DR1, and may be disposed to each correspond to the display cell areas 3010 of the backplane substrate 3002.

The grid area 2320 may be an area excluding the mask cell areas 2310 in the membrane 2200. The grid area 2320 may be disposed on an edge of the mask frame 2100 and on the lip area 2120 of the mask frame 2100.

In addition, the membrane 2200 may include an inorganic film layer 2210 and a nitride layer 2220.

The inorganic film layer 2210 may be disposed on the mask frame 2100. In some embodiments, the inorganic film layer 2210 may be disposed on the mask frame 2100 so that a lower surface thereof is in contact with an upper surface of the mask frame 2100. The inorganic film layer 2210 may include or be made of a material having an etching selectivity with respect to the nitride layer 2220 and the mask frame 2100. In an embodiment, for example, the inorganic film layer 2210 may include silicon oxide (SiOx).

The nitride layer 2220 may be disposed on the inorganic film layer 2210. In some embodiments, the nitride layer 2220 may be disposed on the inorganic film layer 2210 so that a lower surface thereof is in contact with an upper surface of the inorganic film layer 2210. The nitride layer 2220 may include silicon nitride (SiNx).

Each mask cell area 2310 of the membrane 2200 may include a plurality of pixel openings 2312 that expose the anode electrodes AND during the deposition process. The mask cell areas 2310 may be exposed toward the deposition source 3200 through the cell openings 2110, and the pixel openings 2312 may be defined through the membrane 2200 and be connected to the cell openings 2110. In some embodiments, the pixel openings 2312 may be defined or formed through the inorganic film layer 2210 and the nitride layer 2220 and be connected to the cell openings 2110.

The first rear inorganic film layer 2400 may be disposed below the mask frame 2100. In some embodiments, the first rear inorganic film layer 2400 may be disposed below the mask frame 2100 so that an upper surface thereof is in contact with a lower surface of the mask frame 2100. First rear openings 2410 in communication with the cell openings 2110 may be defined or formed in the first rear inorganic film layer 2400. The first rear inorganic film layer 2400 may include a same material as the inorganic film layer 2210 of the membrane 2200. In an embodiment, for example, the first rear inorganic film layer 2400 may include silicon oxide (SiOx).

The second rear inorganic film layer 2500 may be disposed below the first rear inorganic film layer 2400. In some embodiments, the second rear inorganic film layer 2500 may be disposed below the first rear inorganic film layer 2400 so that an upper surface thereof is in contact with a lower surface of the first rear inorganic film layer 2400. Second rear openings 2510 in communication with the cell openings 2110 and the first rear openings 2410 may be defined or formed in the second rear inorganic film layer 2500. The second rear inorganic film layer 2500 may include a same material as the nitride layer 2220 of the membrane 2200. In an embodiment, for example, the second rear inorganic film layer 2500 may include silicon nitride (SiNx).

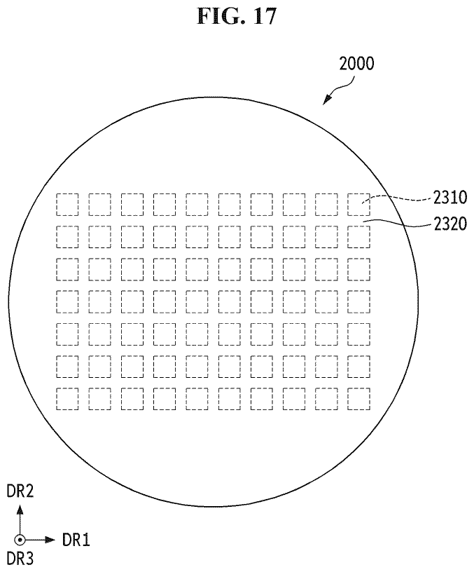

FIG. 17 is a plan view illustrating a state in which the number of mask cell areas in FIG. 14 is changed.

Referring further to FIG. 14, in an embodiment, the number of mask cell areas 2310 disposed in one of the plurality of rows in the first direction DR1 may be equal to the number of mask cell areas 2310 disposed in one of the plurality of columns in the second direction DR2. In such an embodiment where the number of mask cell areas 2310 disposed in one of the plurality of rows in the first direction DR1 and the number of mask cell areas 2310 disposed in one of the plurality of columns in the second direction DR2 are equal to each other, initial stress uniformity and density uniformity may be increased. When the initial stress uniformity of the deposition mask 2000 is increased, stress may be evenly distributed on the deposition mask 2000. As the stress is evenly distributed on the deposition mask 2000, the stress may be effectively prevented from being concentrated on a specific portion of the deposition mask 2000. Accordingly, global warpage that may occur in the deposition mask 2000 may be substantially reduced. In a case where the density uniformity of the deposition mask 2000 is increased, density may be evenly distributed on the deposition mask 2000. As the density is evenly distributed on the deposition mask 2000, the density may be effectively prevented from being concentrated on a specific portion of the deposition mask 2000. Accordingly, global warpage that may occur in the deposition mask 2000 may be substantially reduced.

Referring further to FIG. 17, in an embodiment, the number of mask cell areas 2310 disposed in one of the plurality of rows in the first direction DR1 may be greater than the number of mask cell areas 2310 disposed in one of the plurality of columns in the second direction DR2. The number of mask cell areas 2310 disposed in one of the plurality of columns in the second direction DR2 may be 70% or greater and 100% or less of the number of mask cell areas 2310 disposed in one of the plurality of rows in the first direction DR1. In an embodiment, for example, when the number of mask cell areas 2310 disposed in one of the plurality of rows in the first direction DR1 is 10, the number of mask cell areas 2310 disposed in one of the plurality of columns in the second direction DR2 may be 7 or greater and 10 or less. This may be expressed as the following Inequality 1.

$$\vert 1 - \frac{CY}{CX} \vert \leq 0.3 \qquad < Inequality 1 >$$

In Inequality 1, CX denotes the number of mask cell areas 2310 disposed in one row, and CY denotes the number of mask cell areas 2310 disposed in one column.

When CX is 10 and CY is 7 to 10, Inequality 1 is satisfied. Therefore, the initial stress uniformity and density uniformity of the deposition mask 2000 may be increased. On the other hand, when CX is 10 and CY is 6 or less, Inequality 1 is not satisfied. Therefore, as the initial stress uniformity and density uniformity of the deposition mask 2000 is decreased, the global warpage may not occur in the deposition mask 2000.

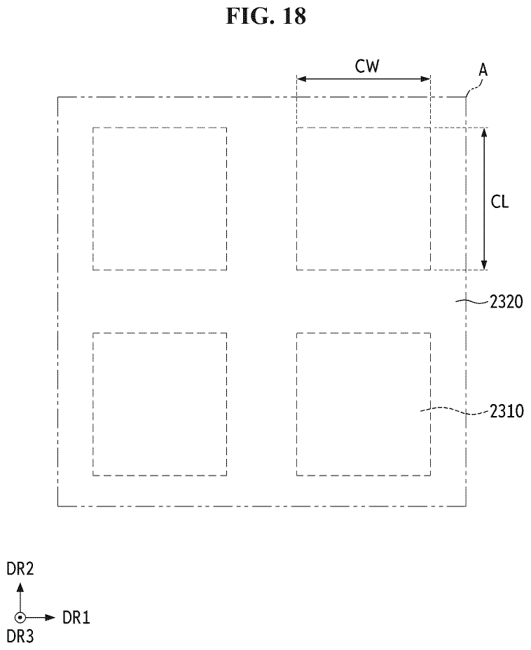

FIG. 18 is an enlarged view of part A of FIG. 14.

Referring to FIG. 18, the plurality of mask cell areas 2310 may be formed to have a same size as each other. A length CW of each mask cell area 2310 in the first direction DR1 may be equal to a length CL of each mask cell area 2310 in the second direction DR2. In such an embodiment the length CW of each mask cell area 2310 in the first direction DR1 and the length CL of each mask cell area 2310 in the second direction DR2 are equal to each other, initial stress uniformity and density uniformity may be increased. When the initial stress uniformity of the deposition mask 2000 is increased, stress may be evenly distributed on the deposition mask 2000. As the stress is evenly distributed on the deposition mask 2000, the stress may be effectively prevented from being concentrated on a specific portion of the deposition mask 2000. Accordingly, global warpage that may occur in the deposition mask 2000 may be substantially reduced. In a case where the density uniformity of the deposition mask 2000 is increased, density may be evenly distributed on the deposition mask 2000. As the density is evenly distributed on the deposition mask 2000, the density may be effectively prevented from being concentrated on a specific portion of the deposition mask 2000. Accordingly, global warpage that may occur in the deposition mask 2000 may be substantially reduced.

The length CW of the mask cell area 2310 in the first direction DR1 may be longer than the length CL of the mask cell area 2310 in the second direction DR2. The length CL of the mask cell area 2310 in the second direction DR2 may be 70% or greater and 100% or less of the length CW of the mask cell area 2310 in the first direction DR1. For example, when the length CW of the mask cell area 2310 in the first direction DR1 is about 10 micrometers (μm), the length CL of the mask cell area 2310 in the second direction DR2 may be about 7 μm or greater and about 10 μm or less. This may be expressed as the following Inequality 2.

$$\vert 1 - \frac{CL}{CW} \vert \leq 0.3 \qquad < Inequality 2 >$$

In Inequality 2, CW denotes a length of the mask cell area 2310 in the first direction DR1, and CL denotes a length of the mask cell area 2310 in the second direction DR2.

When CW is about 10 μm and CL is in a range of about 7 μm to about 10 μm, Inequality 2 is satisfied. Therefore, the initial stress uniformity and density uniformity of the deposition mask 2000 may be increased. On the other hand, when CW is about 10 μm and CL is about 6 μm or less, Inequality 2 is not satisfied. Therefore, as the initial stress uniformity and density uniformity of the deposition mask 2000 is decreased, the global warpage may not occur in the deposition mask 2000.

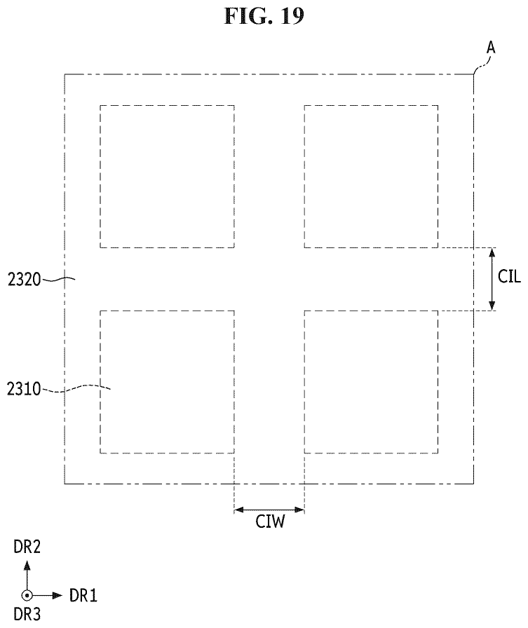

FIG. 19 is an enlarged view of part A of FIG. 14.

Referring to FIG. 19, in an embodiment, a length CIW of a gap between the mask cell areas 2310 in the first direction DR1 may be equal to a length CIL of a gap between the mask cell areas 2310 in the second direction DR2. In such an embodiment where the length CIW of the gap between the mask cell areas 2310 in the first direction DR1 and the length CIL of the gap between the mask cell areas 2310 in the second direction DR2 are equal to each other, initial stress uniformity and density uniformity may be increased. When the initial stress uniformity of the deposition mask 2000 is increased, stress may be evenly distributed on the deposition mask 2000. As the stress is evenly distributed on the deposition mask 2000, the stress may be prevented from being concentrated on a specific portion of the deposition mask 2000. Accordingly, global warpage that may occur in the deposition mask 2000 may be substantially reduced. In a case where the density uniformity of the deposition mask 2000 is increased, density may be evenly distributed on the deposition mask 2000. As the density is evenly distributed on the deposition mask 2000, the density may be effectively prevented from being concentrated on a specific portion of the deposition mask 2000. Accordingly, global warpage that may occur in the deposition mask 2000 may be substantially reduced.

In an embodiment, the length CIW of the gap between the mask cell areas 2310 in the first direction DR1 may be longer than the length CIL of the gap between the mask cell areas 2310 in the second direction DR2. The length CIL of the gap between the mask cell areas 2310 in the second direction DR2 may be 70% or greater and 100% or less of the length CIW of the gap between the mask cell areas 2310 in the first direction DR1. For example, when the length CIW of the length of the gap between the mask cell areas 2310 in the first direction DR1 is about 10 μm, the length CIL of the gap between the mask cell areas 2310 in the second direction DR2 may be about 7 μm or greater and about 10 μm or less. This may be expressed as the following Inequality 3.

$$\vert 1 - \frac{CIL}{CIW} \vert \leq 0.3 \qquad < Inequality 3 >$$

In Inequality 3, CIW denotes a length of the gap between the mask cell areas 2310 in the first direction DR1, and CIL denotes a length of the gap between the mask cell areas 2310 in the second direction DR2.

When CIW is about 10 μm and CIL is in a range of about 7 μm to about 10 μm, Inequality 3 is satisfied. Therefore, the initial stress uniformity and density uniformity of the deposition mask 2000 may be increased. On the other hand, when CIW is about 10 μm and CIL is about 6 μm or less, Inequality 3 is not satisfied. Therefore, as the initial stress uniformity and density uniformity of the deposition mask 2000 is decreased, the global warpage may not occur in the deposition mask 2000.

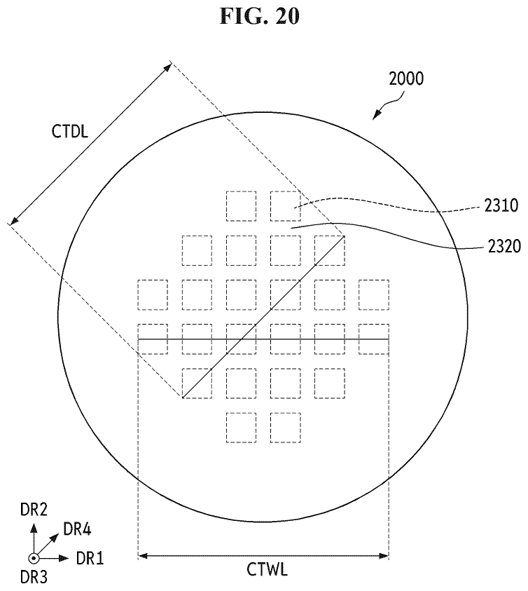

FIG. 20 is a plan view illustrating a state in which an arrangement shape of the mask cell areas in FIG. 14 is changed.

Referring to FIG. 20, the number of mask cell areas 2310 disposed in each row may gradually decrease from a row disposed on a center side (or a center portion) of the membrane 2200 to a row disposed in an outer side (or an outer portion) of the membrane 2200 in the second direction DR2, and the number of mask cell areas 2310 disposed in each column may gradually decrease from a column disposed on a center side of the membrane 2200 to a column disposed in an outer side of the membrane 2200 in the first direction DR1. In some embodiments, the mask cell areas 2310 may be arranged in a cross shape in the membrane 2200.

The total length CTWL of the mask cell areas 2310 on an imaginary line passing through the center side of the membrane 2200 and extending in the first direction DR1 may be equal to the total length CTDL of the mask cell areas 2310 on an imaginary line passing through the center side of the membrane 2200 and extending in the fourth direction DR4. Here, the total length CTWL of the mask cell areas 2310 on the imaginary line extending in the first direction DR1 may be a length of only the pure mask cell areas 2310 excluding the length of the gap between the mask cell areas 2310. The total length CTDL of the mask cell areas 2310 on the imaginary line extending in the fourth direction DR4 may be a length of only the pure mask cell areas 2310 excluding the length of the gap between the mask cell areas 2310. In addition, the first direction DR1 may be orthogonal to the second direction DR2, and the fourth direction DR4 may intersect the first direction DR1 or the second direction DR2 at an angle of about 45°.

In such an embodiment where the total length CTWL of the mask cell areas 2310 on the imaginary line extending in the first direction DR1 and the total length CTDL of the mask cell areas 2310 on the imaginary line extending in the fourth direction DR4 are equal to each other, initial stress uniformity and density uniformity may be increased. When the initial stress uniformity of the deposition mask 2000 is increased, stress may be evenly distributed on the deposition mask 2000. As the stress is evenly distributed on the deposition mask 2000, the stress may be prevented from being concentrated on a specific portion of the deposition mask 2000. Accordingly, global warpage that may occur in the deposition mask 2000 may be substantially reduced. In addition, when the density uniformity of the deposition mask 2000 is increased, density may be evenly distributed on the deposition mask 2000. As the density is evenly distributed on the deposition mask 2000, the density may be effectively prevented from being concentrated on a specific portion of the deposition mask 2000. Accordingly, global warpage that may occur in the deposition mask 2000 may be substantially reduced.

In an embodiment, the total length CTWL of the mask cell areas 2310 on the imaginary line extending in the first direction DR1 may be longer than the total length CTDL of the mask cell areas 2310 on the imaginary line extending in the fourth direction DR4. The total length CTDL of the mask cell areas 2310 on the imaginary line extending in the fourth direction DR4 may be 70% or greater and 100% or less of the total length CTWL of the mask cell areas 2310 on the imaginary line extending in the first direction DR1. When the total length CTWL of the mask cell areas 2310 on the imaginary line extending in the first direction DR1 is about 10 μm, the total length CTDL of the mask cell areas 2310 on the imaginary line extending in the fourth direction DR4 may be about 7 μm or greater and about 10 μm or less. This may be expressed as the following Inequality 4.

$$\vert 1 - \frac{CTDL}{CTWL} \vert \leq 0.3 \qquad < Inequality 4 >$$

In Inequality 4, CTWL denotes the total length of the mask cell areas 2310 on the imaginary line extending in the first direction DR1, and CTDL denotes the total length CTDL of the mask cell areas 2310 on the imaginary line extending in the fourth direction DR4.

When CTWL is about 10 μm and CTDL is in a range of about 7 μm to about 10 μm, Inequality 4 is satisfied. Therefore, the initial stress uniformity and density uniformity of the deposition mask 2000 may be increased. On the other hand, when CTWL is 10 μm and CTDL is 6 μm or less, Inequality 4 is not satisfied. Therefore, as the initial stress uniformity and density uniformity of the deposition mask 2000 is decreased, the global warpage may not occur in the deposition mask 2000.

The display device according to an embodiment of the present disclosure can be applied to various electronic devices. The electronic device according to an embodiment of the present disclosure includes the display device described above, and may further include modules or devices having additional functions in addition to the display device.

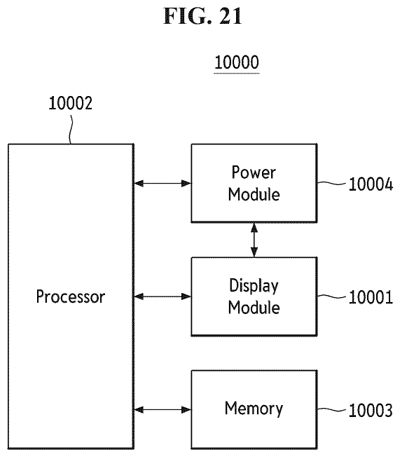

FIG. 21 is a block diagram of an electronic device according to an embodiment of the present disclosure.

Referring to FIG. 21, the electronic device 10000 according to an embodiment of the present disclosure may include a display module 10001, a processor 10002, a memory 10003, and a power module 10004.

The processor 10002 may include at least one selected from a central processing unit (CPU), an application processor (AP), a graphic processing unit (GPU), a communication processor (CP), an image signal processor (ISP), and a controller.

The memory 10003 may store data information to be used for the operation of the processor 10002 or the display module 10001. When the processor 10002 executes an application stored in the memory 10003, an image data signal and/or an input control signal is transmitted to the display module 10001, and the display module 10001 can process the received signal and output image information through a display screen.

The power module 10004 may include a power supply module such as, for example a power adapter or a battery, and a power conversion module that converts the power supplied by the power supply module to generate power necessary for the operation of the electronic device 10000.

At least one of the components of the electronic device 10000 according to an embodiment of the present disclosure may be included in the display device according to the embodiments of the present disclosure. In addition, some modules of the individual modules functionally included in one module may be included in the display device, and other modules may be provided separately from the display device. In an embodiment, for example, the display device may include the display module 10001, and the processor 10002, the memory 10003, and the power module 10004 may be provided in the form of other devices within the electronic device 10000 other than the display device.

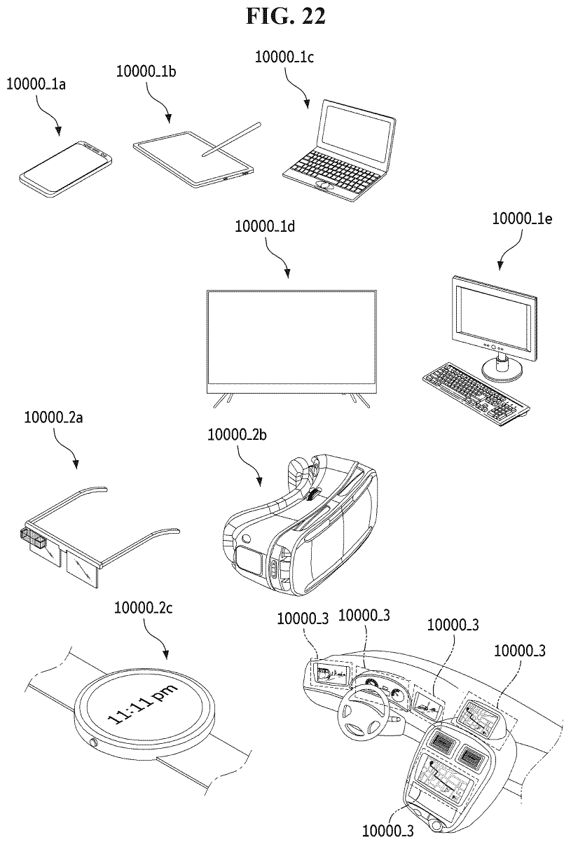

FIG. 22 is a schematic diagram of an electronic device according to various embodiments of the present disclosure.

Referring to FIG. 22, various electronic devices to which display devices according to embodiments of the present disclosure are applied may include not only image display electronic devices such as a smart phone 10000_1a, a tablet PC 10000_1b, a laptop 10000_1c, a TV 10000_1d, and a desk monitor 10000_1e, but also wearable electronic devices including display modules such as, for example smart glasses 10000_2a, a head mounted display 10000_2b, and a smart watch 10000_2c, and vehicle electronic devices 10000_3 including display modules such as a center information display (CID) and a room mirror display arranged on a dashboard, center fascia, and dashboard of an automobile.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask frame in which a cell opening is defined; and
a membrane disposed on the mask frame and partitioned into a mask cell area disposed on the cell opening and a grid area disposed on the mask frame not to overlap the cell opening,
wherein a plurality of mask cell areas is defined in the membrane, and the mask cell areas are disposed in a matrix form having a plurality of rows in a first direction and a plurality of columns in a second direction intersecting the first direction.

2. The deposition mask of claim 1, wherein a number of the mask cell areas disposed in one of the plurality of rows is equal to or greater than a number of the mask cell areas disposed in one of the plurality of columns.

3. The deposition mask of claim 1, wherein a number of the mask cell areas disposed in one of the plurality of columns is 70% or greater and 100% or less of a number of the mask cell areas disposed in one of the plurality of rows.

4. The deposition mask of claim 1, wherein a number of the mask cell areas disposed in one of the plurality of rows and a number of the mask cell areas disposed in one of the plurality of columns satisfy the following inequality:
$$\vert 1 - \frac{CY}{CX} \vert \leq 0.3 ,$$
wherein
CX denotes the number of the mask cell areas disposed in the one of the plurality of rows, and
CY denotes the number of the mask cell areas disposed in the one of the plurality of columns.

5. The deposition mask of claim 1, wherein the plurality of mask cell areas has a same size as each other.

6. The deposition mask of claim 5, wherein a length of the mask cell area in the first direction is equal to or length than a length of the mask cell area in the second direction.

7. The deposition mask of claim 5, wherein a length of the mask cell area in the second direction is 70% or greater and 100% or less of a length of the mask cell area in the first direction.

8. The deposition mask of claim 5, wherein a length of the mask cell area in the first direction and a length of the mask cell area in the second direction satisfy the following inequality:
$$\vert 1 - \frac{CL}{CW} \vert \leq 0.3 ,$$
wherein
CW denotes the length of the mask cell area in the first direction, and
CL denotes the length of the mask cell area in the second direction.

9. The deposition mask of claim 1, wherein a length of a gap between the mask cell areas in the first direction is equal to or longer than a length of a gap between the mask cell areas in the second direction.

10. The deposition mask of claim 1, wherein a length of a gap between the mask cell areas in the second direction is 70% or greater and 100% or less of a length of a gap between the mask cell areas in the first direction.

11. The deposition mask of claim 1, wherein a length of a gap between the mask cell areas in the first direction and a length of a gap between the mask cell areas in the second direction satisfy the following inequality:
$$\vert 1 - \frac{CIL}{CIW} \vert \leq 0.3 ,$$
wherein
CIW denotes the length of the gap between the mask cell areas in the first direction, and
CIL denotes the length of the gap between the mask cell areas in the second direction.

12. The deposition mask of claim 1, wherein a number of the mask cell areas disposed in each row gradually decreases from a row disposed on a center side of the membrane to a row disposed in an outer side of the membrane in the second direction, and
a number of the mask cell areas disposed in each column gradually decreases from a column disposed on a center side of the membrane to a column disposed in an outer of the membrane in the first direction.

13. The deposition mask of claim 12, wherein a total length of the mask cell areas on an imaginary line passing through the center side of the membrane and extending in the first direction is equal to or longer than a total length of the mask cell areas on an imaginary line passing through the center side of the membrane and extending in a fourth direction intersecting the first direction and the second direction.

14. The deposition mask of claim 13, wherein the first direction and the second direction are orthogonal to each other, and
the fourth direction intersects the first direction or the second direction at an angle of about 45°.

15. The deposition mask of claim 12, wherein a total length of the mask cell areas on an imaginary line passing through the center side of the membrane and extending in a fourth direction intersecting the first direction and the second direction is 70% or greater and 100% or less of a total length of the mask cell areas on an imaginary line passing through the center side of the membrane and extending in the first direction.

16. The deposition mask of claim 12, wherein a total length of the mask cell areas on an imaginary line passing through the center side of the membrane and extending in the first direction and a total length of the mask cell areas on an imaginary line passing through the center side of the membrane and extending in a fourth direction intersecting the first direction and the second direction satisfy the following inequation:
$$\vert 1 - \frac{CTDL}{CTWL} \vert \leq 0.3 ,$$
wherein
CTWL denotes the total length of the mask cell areas on the imaginary line extending in the first direction, and
CTDL denotes the total length of the mask cell areas on the imaginary line extending in the fourth direction.

17. The deposition mask of claim 1, wherein a plurality of pixel openings is defined through the membrane in the mask cell area.

18. The deposition mask of claim 1, wherein the membrane includes:
an inorganic film layer disposed on the mask frame; and
a nitride layer disposed on the inorganic film layer.

19. The deposition mask of claim 18, further comprising:
a first rear inorganic film layer disposed below the mask frame with a first rear opening defined therein;
a second rear inorganic film layer disposed below the first rear inorganic film layer with a second rear opening defined therein,
wherein the first rear inorganic film layer includes a same material as the inorganic film layer, and
the second rear inorganic film layer includes a same material as the nitride layer.

20. An electronic device comprising:
a display device manufactured by using a deposition mask;
the deposition mask comprising:
a mask frame in which a cell opening is defined; and
a membrane disposed on the mask frame and partitioned into a mask cell area disposed on the cell opening and a grid area disposed on the mask frame not to overlap the cell opening,
wherein a plurality of mask cell areas is provided in the membrane, and the mask cell areas are disposed in a matrix form having a plurality of rows in a first direction and a plurality of columns in a second direction intersecting the first direction.
